(19) United States
(12) Patent Application Publication
(10) Pub. No.: US 2026/0025950 A1
(43) Pub. Date: Jan. 22, 2026

(54) COOLING SYSTEM WITH INRUSH CURRENT LIMITER CIRCUITS

(71) Applicant: Hoffman Enclosures Inc., Anoka, MN (US)

(72) Inventors: Gabriel T.A. Schaap, Anoka, MN (US); Oliver Kistner, Pforzheim (DE)

(21) Appl. No.: 19/273,599

(22) Filed: Jul. 18, 2025

Related U.S. Application Data
(60) Provisional application No. 63/672,883, filed on Jul. 18, 2024.

(51) Int. Cl. H05K 7/20; H02H 9/00; H02H 9/02

(52) U.S. Cl. CPC H05K 7/20281; H02H 9/004; H02H 9/025; H05K 7/20172; H05K 7/20209; H05K 7/20272

(57) ABSTRACT

An example cooling system includes a power source, a first pump cassette configured to circulate fluid through the cooling system, and a second pump cassette configured to circulate fluid through the cooling system. The first pump cassette is connected to the power source and includes a first inrush current limiter circuit and a first pump controller. The second pump cassette is also connected to the power source and includes a second inrush current limiter circuit and a second pump controller. The first inrush current limiter circuit is connected in series between the power source and the first pump controller, and the second inrush current limiter circuit is connected in series between the power source and the second pump controller.

### CROSS REFERENCE TO RELATED APPLICATION

This application is based on and claims priority to U.S. Provisional Patent Application No. 63/672,883, filed on Jul. 18, 2024, the entire disclosure of which is incorporated herein by reference.

### BACKGROUND

Cooling systems can be provided for electrical components in data centers. In some cases, equipment in a data center can be cooled through various means, including through liquid-based cooling systems, air-based cooling systems, or combinations thereof. Electrical equipment within a data center can be housed in racks and can include piping and manifolds for receiving a liquid coolant pumped through a liquid cooling circuit. The liquid coolant can be delivered to components of electrical equipment to provide a heat transfer from those components to the heat of the liquid coolant circuit. In certain applications, various components of these cooling systems can experience undesirable electrical characteristics, such as unexpectedly high inrush currents. Systems and methods that can provide more desirable electrical characteristics as well as improvements in terms of manufacturability are generally desired.

### BRIEF DESCRIPTION OF THE DRAWINGS

FIG. 1 shows a schematic diagram of an example cooling system, in accordance with some aspects of the disclosure.

FIG. 2 shows an isometric view of an example liquid-to-air cooling unit that can be used in the cooling system of FIG. 1, in accordance with some aspects of the disclosure.

FIG. 3 shows a rear isometric view of the liquid-to-air cooling unit of FIG. 2, in accordance with some aspects of the disclosure.

FIG. 4 shows a front elevation view of the liquid-to-air cooling unit of FIG. 2, in accordance with some aspects of the disclosure.

FIG. 5 shows a front, right isometric view of the liquid-to-air cooling unit of FIG. 2 with side panels of the unit removed, in accordance with some aspects of the disclosure.

FIG. 6 shows a rear, left isometric view of the liquid-to-air cooling unit of FIG. 2 with side panels of the unit removed, in accordance with some aspects of the disclosure.

FIG. 7 shows a section view illustrating an example liquid-to-air heat exchanger of the liquid-to-air cooling unit of FIG. 2, in accordance with some aspects of the disclosure.

FIG. 8 shows a top view illustrating the example liquid-to-air heat exchanger of FIG. 7, in accordance with some aspects of the disclosure.

FIG. 9 shows a section view illustrating an example mounting bracket of the liquid-to-air cooling unit of FIG. 2, in accordance with some aspects of the disclosure.

FIG. 10 shows a partial top view illustrating example plumbing components of the liquid-to-air cooling unit of FIG. 2, in accordance with some aspects of the disclosure.

FIG. 11 shows a partial bottom view illustrating example plumbing components of the liquid-to-air cooling unit of FIG. 2, in accordance with some aspects of the disclosure.

FIG. 12 shows a partial bottom view illustrating example pump cassettes of the liquid-to-air cooling unit of FIG. 2, in accordance with some aspects of the disclosure.

FIG. 13 shows an isometric view illustrating an example manifold of the liquid-to-air cooling unit of FIG. 2, in accordance with some aspects of the disclosure.

FIG. 14 shows a first isometric view illustrating an example filter assembly of the liquid-to-air cooling unit of FIG. 2, in accordance with some aspects of the disclosure.

FIG. 15 shows a second isometric view illustrating an example filter assembly of the liquid-to-air cooling unit of FIG. 2, in accordance with some aspects of the disclosure.

FIG. 16 shows a rear isometric view illustrating example expansion tanks of the liquid-to-air cooling unit of FIG. 2, in accordance with some aspects of the disclosure.

FIG. 17 shows a first isometric view illustrating the example liquid-to-air heat exchanger of FIG. 7, in accordance with some aspects of the disclosure.

FIG. 18 shows a second isometric view illustrating the example liquid-to-air heat exchanger of FIG. 7, in accordance with some aspects of the disclosure.

FIG. 19 shows a front view illustrating an example fan of the liquid-to-air cooling unit of FIG. 2, in accordance with some aspects of the disclosure.

FIG. 20 shows a rear view illustrating an example fan of the liquid-to-air cooling unit of FIG. 2, in accordance with some aspects of the disclosure.

FIG. 21 shows an isometric view illustrating an example control unit of the liquid-to-air cooling unit of FIG. 2, in accordance with some aspects of the disclosure.

FIG. 22 shows an isometric view illustrating an example power supply unit of the liquid-to-air cooling unit of FIG. 2, in accordance with some aspects of the disclosure.

FIG. 23 shows another isometric view illustrating an example power supply unit of the liquid-to-air cooling unit of FIG. 2, in accordance with some aspects of the disclosure.

FIG. 24 shows an isometric view illustrating an example interface board of the liquid-to-air cooling unit of FIG. 2, in accordance with some aspects of the disclosure.

FIG. 25 shows an example schematic diagram representing different components and functionality of the liquid-to-air cooling unit of FIG. 2, in accordance with some aspects of the disclosure.

FIG. 26 shows another example schematic diagram representing different components and functionality of the liquid-to-air cooling unit of FIG. 2, in accordance with some aspects of the disclosure.

FIG. 27 shows a block diagram illustrating a first example feedback control system that can be used in the liquid-to-air cooling unit of FIG. 2, in accordance with some aspects of the disclosure.

FIG. 28 shows a block diagram illustrating a second example feedback control system that can be used in the liquid-to-air cooling unit of FIG. 2, in accordance with some aspects of the disclosure.

FIGS. 29A-29E show a schematic diagram illustrating an example controller and an example interface board that can be used in the liquid-to-air cooling unit of FIG. 2, in accordance with some aspects of the disclosure.

FIGS. 30A-30D show tables illustrating examples of sensors that can be used in the liquid-to-air cooling unit of FIG. 2, in accordance with some aspects of the disclosure.

FIG. 31 shows a block diagram illustrating an example control system that can be used in the liquid-to-air cooling unit of FIG. 2, in accordance with some aspects of the disclosure.

FIG. 32 shows a block diagram illustrating an example controller that can be used in the liquid-to-air cooling unit of FIG. 2, in accordance with some aspects of the disclosure.

FIG. 33 shows a flow diagram illustrating an example process for controlling operation of the liquid-to-air cooling unit of FIG. 2, in accordance with some aspects of the disclosure

FIG. 34 is a block diagram showing example inrush current limiter circuits that can be used in the liquid-to-air cooling unit of FIG. 2, in accordance with some aspects of the disclosure.

FIG. 35 is another block diagram showing the inrush current limiter circuits of FIG. 34, in accordance with some aspects of the disclosure.

FIG. 36 is a perspective illustration showing an example implementation of one of the inrush current limiter circuits of FIG. 34, in accordance with some aspects of the disclosure.

FIG. 37 is a schematic diagram showing an example switched-mode power supply circuit that can be used the inrush current limiter circuits of FIG. 34, in accordance with some aspects of the disclosure.

FIG. 38 is a schematic diagram showing an example switching circuit that can be used the inrush current limiter circuits of FIG. 34, in accordance with some aspects of the disclosure.

### DETAILED DESCRIPTION

The following discussion is presented to enable a person skilled in the art to make and use aspects of the disclosure. Various modifications to the illustrated examples will be readily apparent to those skilled in the art, and the generic principles herein can be applied to other applications without departing from the disclosure. Thus, implementations of the disclosure are not intended to be limited to the examples shown but are to be accorded the widest scope consistent with the principles and features disclosed herein. The following detailed description is to be read with reference to the figures, in which like elements in different figures have like reference numerals. The figures, which are not necessarily to scale, depict selected examples and are not intended to limit the scope of the disclosure. Skilled artisans will recognize the examples provided herein have many useful alternatives that fall within the scope of the disclosure.

Cooling systems can be provided for data centers to cool electrical components within a data center. During operation, electrical components, typically housed in racks having a standard rack footprint (e.g., a standard height, width, and depth), generate heat. As that heat may degrade electrical components, damage the systems, or degrade performance of the components, cooling systems can be provided for data centers for transferring heats away from racks of the data center with electrical components that need to be cooled.

Cabinets or racks containing electrical equipment are typically arranged in rows within a data center, defining aisles between consecutive rows. Racks can be pre-assembled and “rolled in” to a space in the row adjacent to other racks, the space being pre-defined to have the footprint of a standard rack. This arrangement allows a modular construction of or addition to components in a data center. In some configurations, aisles on opposite sides of a row of cabinets can be alternately designated as a cold aisle, or a hot aisle, and heat generated by the electrical components of a cabinet can be expelled to the hot air aisle.

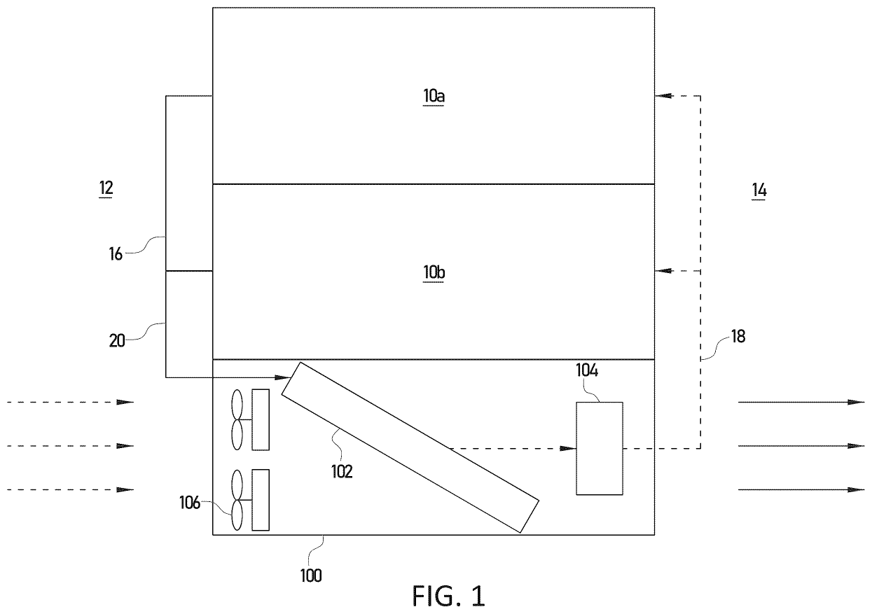

Referring to FIG. 1, a schematic diagram of an example cooling system 1 is shown, in accordance with some aspects of the disclosure. As noted, electrical equipment in a data center (e.g., servers, storage devices, networking devices, etc.) can generate heat in operation and can require cooling systems to dissipate or transfer heat away from the electrical components. As shown in FIG. 1, the cooling system 1 includes both a cabinet 10a and a cabinet 10b for housing electrical equipment that can be a load of the cooling system 1. As shown, the cabinets 10a, 10b are arranged in a row, with a front side of each of the cabinets 10a, 10b facing a cold aisle 12 and a rear side of each of the cabinets 10a, 10b facing a hot aisle 14. Both of the cabinets 10a, 10b can be positioned in the flow path of a liquid coolant circuit 16 (e.g., a liquid cooling loop) such that a coolant of the liquid coolant circuit 16 can flow through the cabinets 10a, 10b to transfer heat from electrical components in the cabinets 10a, 10b. For example, the liquid coolant circuit 16 can include a cold side 18 having a cooled fluid and a hot side 20 having a heated fluid.

As shown, coolant from the cold side 18 can flow into each of the cabinets 10a, 10b, and can be heated by a heat transferred to the fluid from electrical components within the cabinets 10a, 10b. The heated fluid can then flow out of the electrical cabinets 10a, 10b to the hot side 20 of the liquid coolant circuit 16 to transfer the heat away from the respective electrical cabinets 10a, 10b. In some examples, the liquid coolant within a liquid coolant circuit (e.g., liquid coolant circuit 16) can be water. In other examples, the liquid coolant can be a dielectric fluid, or another suitable type of coolant such as a propylene glycol or a combination of water and an anti-corrosion agent.

While the above description of the cooling system 1 references cabinets of electrical equipment within a data center, it should be noted that the disclosure is not limited to cooling electrical cabinets within a data center and can be equally applicable to any application or use case requiring liquid cooling. For example, cabinets along a first liquid coolant circuit (e.g., one or more of cabinets 10a, 10b along liquid coolant circuit 16) can house liquid to liquid heat exchangers which can transfer heat from a coolant of a second liquid coolant circuit to the liquid of the first liquid coolant circuit. In some cases, liquid cooling circuits and systems can be provided for power supply systems, and can be used to cool batteries, transformers, power converters, electric motors, and the like. In some cases, liquid coolant circuits consistent with this disclosure can be used to cool thermal loads outside of data centers.

The cooling system 1 can include liquid-to-air cooling units to transfer heat from a liquid of a liquid cooling circuit (e.g., liquid coolant circuit 16) to an air of a data center (e.g., air of the hot aisle 14). As will be discussed further, the in-row cooling unit can be housed in a rack having a standard rack footprint for modular assembly, ease of installation and integration within a data center. In other examples, the footprint of an in-row cooling unit may be smaller than a standard rack footprint. As further illustrated in FIG. 1, the cooling system 1 can include an in-row liquid-to-air cooling unit 100 (LACU) for transferring heat from the fluid of the liquid coolant circuit 16 to air of the hot aisle 14. The LACU 100 can be housed in a rack, within an aisle of electrical equipment. For example, as shown in FIG. 1, the LACU 100 can be in a row with electrical cabinets 10a, 10b along the liquid coolant circuit 16, with a front of the LACU 100 facing the cold aisle 12 and a rear of the LACU facing the hot aisle 14.

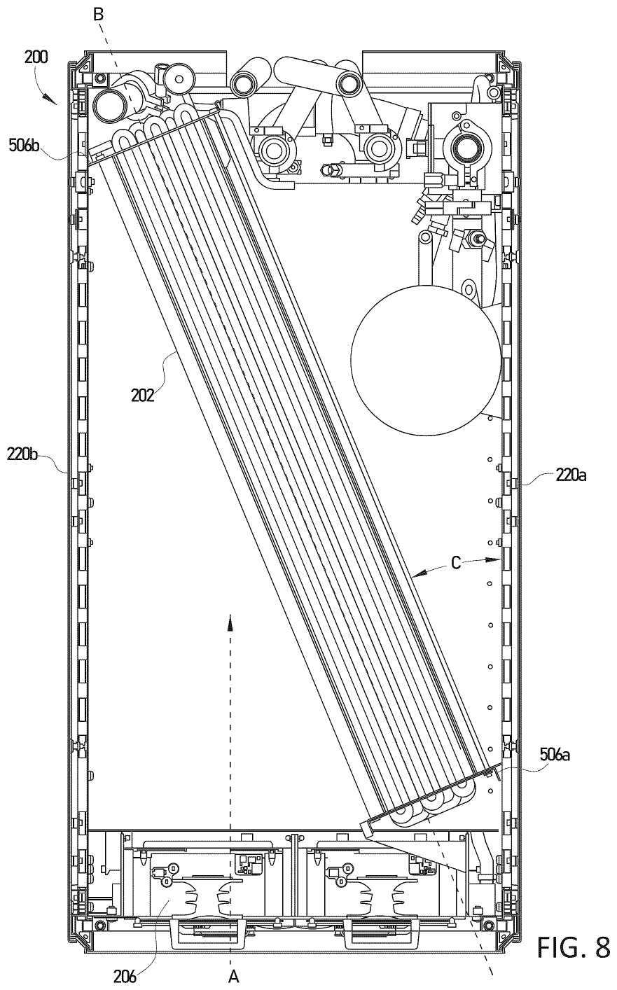

The LACU 100 can include a liquid-to-air heat exchanger 102 (HX) for transferring a heat from fluid in the liquid coolant circuit 16 to air of the data center (e.g., air of the hot aisle 14). The liquid from the hot side 20 of the liquid coolant circuit 16 can enter the HX 102, and the liquid can exit the HX 102 to the cold side 18 of the liquid coolant circuit 16. A surface area of a liquid to air heat exchanger can correspond to a rate of heat transfer from a liquid to air, and a greater surface area of the heat exchanger can correspond to a greater rate of heat transfer. Thus, a heat exchanger of a liquid-to-air cooling unit can be sized and positioned to provide maximal surface area for heat transfer. For example, as shown in FIG. 1, the HX 102 can be positioned at an oblique angle within the LACU 100 relative to sides of the LACU 100 (e.g., as further described with respect to FIG. 8).

In some examples, the LACU 100 can include air flow components (e.g., fans) to induce a flow of air across a liquid-to-air heat exchanger to increase a heat transfer from liquid of a liquid coolant circuit to an air of the data center. For example, as shown in FIG. 1, the LACU 100 includes one or more fans 106 to induce a flow of air across the HX 102. The one or more fans 106 can be positioned at a front of the LACU 100 and can suck in cool air from the cold aisle 12 and blow the air across the HX 102 in a direction toward the hot aisle 14. In some examples, the fans 106 can be position in a back of one or more of the cabinets 10a, 10b. The fans 106 can suck air from a rear of the LACU 100 across a heat exchanger and blow the air out of a front of the LACU 100 (e.g., air can flow in an opposite direction from the air flow direction shown). As discussed below, the fans 106 of the LACU 100 can be arranged in rows and columns along a front of the LACU 100.

The cooling system 1 can further include one or more pumping units to induce a flow of fluid through the liquid coolant circuit 16. However, in some implementations, the cooling system 1 may not include a pumping unit, but may instead rely on water pressure provided by the facility in which the cooling system is installed. In some examples, the pumping unit can be housed in an in-row liquid-to-air cooling unit (e.g., the liquid-to-air cooling unit can be a coolant distribution unit). For example, as shown in FIG. 1, the LACU 100 includes a pumping unit 104 to pump fluid through the liquid cooling circuit 16. It can be advantageous to pump cool fluid through pumps of a pumping unit, as warm fluid can cause an expansion in components of the pumps, which can decrease a lifetime of the pumps. In some cases, as described below, the pumping unit 104 can include a plurality of pumps.

The pumping unit 104 can be positioned downstream of the HX 102 and along the cold side 18 of the liquid coolant circuit 16. In other examples, the pumping unit 104 can be positioned upstream of a liquid-to-air heat exchanger (e.g., pumps of the liquid-to-air cooling unit can be along a hot side of a liquid cooling circuit). The pumping unit 104 of the LACU 100 can be provided to fit in a standard size slot within a cabinet (e.g., a height of 2 U, or 4 U, or 8 U or occupying four vertical bays of the cabinet). In some examples, a coolant distribution unit (CDU) can be provided in the in-row LACU 100, rather than in the cabinets 10a, 10b housing the electrical equipment.

In FIG. 1, the cold side 18 of the liquid cooling circuit 16 is shown at a front side of each of the cabinets 10a, 10b and the LACU 100, and the hot side 20 is shown at a rear side of the cabinets 10a, 10b and the LACU 100. However, in some applications, it can be advantageous to position liquid entries and exits (e.g., inlet ports and outlet ports) on a same side of a cabinet. For example, liquid manifolds for fluid entry and exit for cabinets can be mounted at a rear of the respective cabinets. In some examples, hosing of a liquid cooling circuit can enter cabinets (e.g., cabinets of electrical equipment or a cabinet of a liquid-to-air cooling unit) from a rear of the cabinet, through an entry in a side panel of the cabinet, from a top entry, or from a bottom entry of the cabinet. Further, a liquid-to-air cooling unit can be provided to cool more than two electrical cabinets, or only one electrical cabinet.

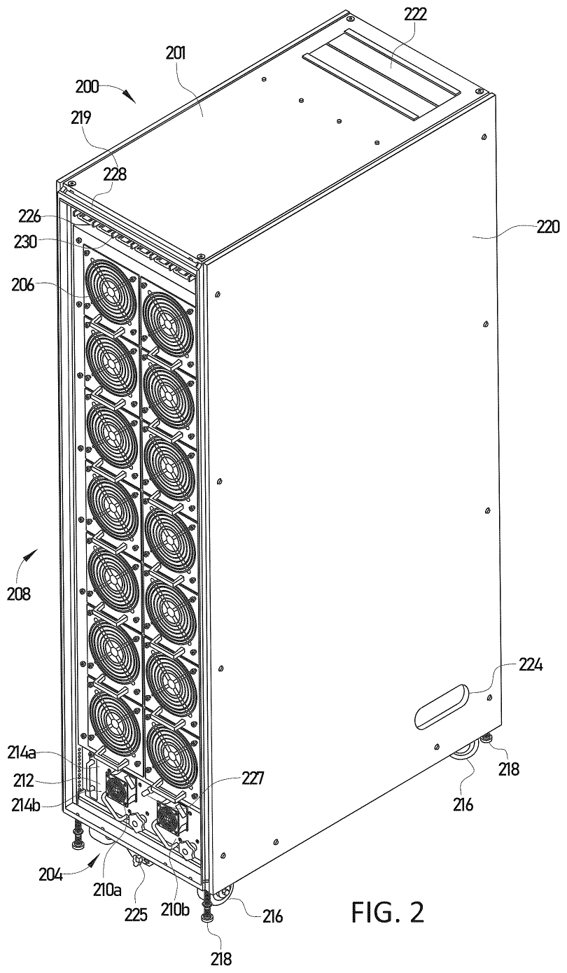

Referring to FIG. 2, an isometric view of an example liquid-to-air cooling unit (LACU) 200 is shown, in accordance with some aspects of the disclosure. The LACU 200 can be the same as or similar to the LACU 100 described above, and can be used with the cooling system 1. The LACU 200 can be referred to generally as a “sidecar” or a coolant distribution unit (CDU), among other possible terms. As shown in FIG. 2, the LACU 200 includes a plurality of fans 206 that can be provided in a fan assembly 208 in a front of the cabinet, as illustrated, which can induce an airflow through the system, increasing the cooling efficiency thereof. As shown in FIG. 2, the fan assembly 208 includes fourteen fans 206 arranged in two columns and seven rows. However, it will be appreciated that the LACU 200 can include more than 14 fans or fewer than 14 fans. Also, it will be appreciated that the fans 206 can be arranged in panels including four fans in a single panel, for example. The fans 206 can be hot-swappable (e.g., individual fans 206 of the fan assembly can be removed, replaced, or serviced without causing a downtime of the LACU 200).

It can be advantageous to position pumping units in a bottom of a rack of the LACU 200 to prevent any leakage of fluid (e.g., liquid leaks during replacement of components of the pumping units) from damaging the electronics of the LACU 200 or electronic components of the data center. For example, as shown in FIG. 2, the LACU 200 includes a replaceable pump unit (RPU) 204. The RPU 204 can be housed beneath the fan assembly 208 and can have a height of four rack units (e.g., the RPU 204 can have a height of 4 U, occupying a space equal to four standard shelves of electrical equipment within a cabinet of a data center). The RPU 204 can include two pump cassettes 210a and 210b, as well as a control unit 212 including two hot-swappable control modules 214a and 214b.

In some examples, the pump cassettes 210a, 210b can be hot-swappable, and can include blind connectors (as detailed below) in a back portion of the pump cassettes 210a, 210b for electrical and fluid connections. The RPU 204 can be implemented in a variety of ways, such as including only one pump cassette, or including more than two pump cassettes. The RPU 204 can also occupy various volumes within the LACU 200 depending on the application (e.g., the RPU 204 can have a height of 8 U in some implementations). The hot-swappable control modules 214a, 214b can be substantially similar such that, when one hot-swappable control module 214a, 214b is removed for servicing or replacement, the other hot-swappable control module 214a, 214b can implement control processes for the LACU 200, as further described below. In some examples, the RPU 204 may not include any control modules (e.g., a main controller for the LACU 200 can be housed at a different location, or external to the LACU 200). The RPU 204 can also include any number of control modules, such as one control module or more than two control modules.

The LACU 200 is further shown to include a fill/drain port 225 for filling the LACU 200 and components of the LACU 200 with liquid coolant (e.g., charging the unit). In some cases, it can be advantageous to provide the fill/drain port 225 at the front of the LACU 200 to be accessible to an operator of the unit from a cold aisle. The liquid fill/drain port 225 is shown to be positioned at a bottom of the LACU 200. Positioning the fill/drain port 225 at a bottom of the LACU 200 can be advantageous, as it can reduce a pressure to drain the system. In some cases, the fill/drain port 225 can comprise a quick disconnect fitting, to provide for an ease of connecting fill or drain lines to the LACU 200. It will be appreciated that the LACU 200 can include any suitable number of fill/drain ports, including, for example, a dedicated fill port and a dedicated drain port. The LACU 200 can also include ports provided at the front of the LACU 200 corresponding to individual components of the LACU 200. For example, as shown, the RPU 204 includes a separate liquid fill/drain port 227 for filling or draining a fluid from the RPU 204. Liquid fill/drain ports can be provided at other locations of the LACU 200, including in the back, along a side, etc.

The LACU 200 as shown in FIG. 2 is housed within a cabinet 201. The cabinet 201 can have a standard rack footprint, and may have a width of 600 millimeters (mm), as can allow the cabinet to be “rolled in” to a cabinet space within a row of cabinets in a data center. The cabinet 201, which can also be referred to as a “rack” or an “enclosure” in some examples (among other possible terms), can have different footprints. For example, the cabinet 201 could also have a width of 1200 mm to occupy a space within a row in a data center that is sized to receive two adjacent racks of equipment. In some cases, the cabinet 201 can occupy a footprint with a width of less than 600 mm, or greater than 600 mm. In some cases, a width or height of the cabinet 201 can be configured to meet a standard, including, for example, an industry standard, or a regulatory standard.

The cabinet 201 can include features to facilitate ease of installation and integration within a data center. For example, as illustrated, the LACU 200 can include a plurality of wheels 216 to allow the LACU 200 to be rolled to a desired location within a data center. The LACU 200 can also include casters and/or a plurality of adjustable feet 218. Before the LACU 200 is in an installation position, the adjustable feet 218 can be positioned at a first height, and at the first height, the adjustable feet 218 do not engage or contact a floor of the data center. Then, when the LACU 200 is installed in a desired location, the adjustable feet 218 can be moved to a second height (e.g., by rotating an adjustable screw), at which point the adjustable feet 218 engage the floor and prevent displacement of the LACU 200 relative to the floor. The LACU 200, in some implementations, may not include the wheels 216 and/or the adjustable feet 218, but can instead include alternative or additional mechanisms for facilitating ease of installation and securing the LACU 200 in place when installed.

The cabinet 201 is shown to include a top panel 219 at a top of the cabinet 201, and one or more side panels 220 at lateral sides of the cabinet 201 (e.g., along vertical sides of the LACU 200 not facing either a hot aisle or a cold aisle). The top panel 219 and the side panels 220 can function to enclose components of the LACU 200, partially define a flow path of air through the cabinet 201, and shield internal components of the LACU 200 from view. Cables for electrical power and hosing for fluid connections can enter the LACU 200 through an open back portion of the LACU 200, in some examples. However, it may be advantageous to provide cable and hose entries for the cabinet 201 at other locations. For example, feeding cables and hoses through a back of the cabinet 201 can increase a depth required for a row housing the LACU 200. In some cases, data centers can be arranged with top feed configurations, with connections (e.g., cables, tubing, hosing etc.) being provided from a ceiling of the data center. In other configurations, the cabinets in a data center are installed on a raised floor, and connections can be provided from a bottom of the cabinet (i.e., in a “bottom feed” configuration). In this regard, panels of the cabinet 201 can include openings, which can sometimes be referred to as apertures or cutouts, to provide an entry for cables and hosing into the cabinet 201 in a variety of manners.

For example, as shown in FIG. 2, the top panel 219 includes a top-feed cutout 222 for receiving cable and hosing from the top of the cabinet 201. Similarly, a bottom-feed cutout can be provided at a bottom of the cabinet 201 for receiving cabling and hosing through the bottom of the cabinet 201. In some cases, it can be advantageous to route hosing directly from adjacent cabinets. For example, providing liquid connections directly from an adjacent cabinet can reduce a pressure needed to pump coolant through a liquid coolant circuit. This configuration can reduce a total length of tubing required for a system, which in turn reduces the power required to pump coolant through the system. Additionally, when routing hosing directly through the cutout in the side panels 220, hosing need not extend out a back portion of either the electrical cabinet or the cabinet housing the cooling system, which may reduce a clearance needed or a total depth of the system. As shown in FIG. 2, the side panels 220 include a side cutout 224 for receiving hosing and/or hosing directly from adjacent cabinets. In some examples, hosing and cabling can enter the cabinet 201 at locations other than illustrated in FIG. 2, including, for example, through a front of the cabinet 201. In some cases, cutouts for receiving hosing into the LACU, such as the side cutout 224, can have an open area that is at least large enough to accommodate 4 hoses having a diameter of 1.5 inches, among other possible dimensions.

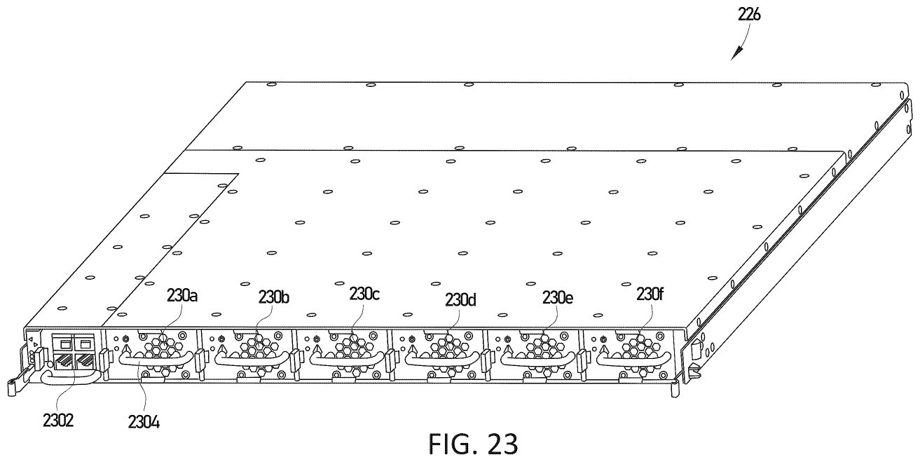

The LACU 200 is also shown to include a power supply unit 226 that controls aspects of electrical power provided to electrical components of the LACU 200. The power supply unit 226 can be implemented in a variety of manners depending on the application. As shown in FIG. 2, the power supply unit 226 can be provided at or near a top of the LACU 200 (e.g., above liquid flow components in the LACU 200). This arrangement can be advantageous, as it can prevent leakage of liquid onto power control elements of the power supply unit 226. The power supply unit 226 can have a height of 1 U, and an empty slot 228 can be provided above the power supply unit 226 also having a height of 1 U. The power supply unit 226 can have various dimensions, such as a height of 2 U. The LACU 200 can include more than one power supply unit, such as two or more power supply units. The power supply unit 226 can include one or more removable power modules 230, as further described with respect to power supply unit 2300 shown in FIG. 23. In the illustrated examples, the power supply unit 226 includes 6 power supply modules, but in other examples, the power supply unit 226 can include only one power supply module, or at least two power supply modules, at least three power supply modules, at least four power supply modules, etc. The power supply unit 226 can receive three phases of power from a power inlet, and individual phases of the three phases can be provided to a respective power supply module. Thus, it can be advantageous to provide power supply modules in multiples of three to allow balancing of phases across power supply modules.

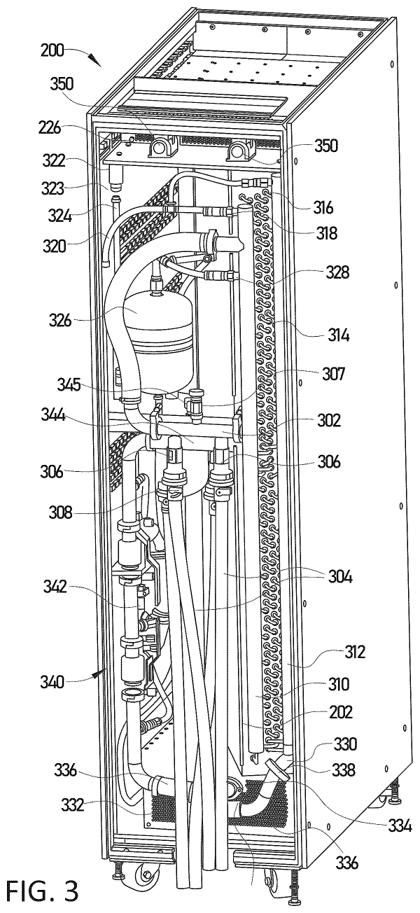

Referring to FIG. 3, a rear isometric view of the example LACU 200 is shown, in accordance with some aspects of the disclosure. From the rear view shown in FIG. 3, plumbing elements of the LACU 200 for directing a flow of fluid through the LACU 200 can be seen. The plumbing elements as shown can be contained in the cabinet 201, for example, to improve ease of servicing and reduce a pressure drop across the plumbing elements that may otherwise be incurred if the plumbing elements were dispersed through the LACU 200. As noted, the LACU 200 can generally receive heated fluid from a hot side of a fluid coolant circuit (e.g., the hot side 20 of the liquid coolant circuit 16 as illustrated in FIG. 1). Accordingly, as shown in FIG. 3, the LACU 200 includes an inlet manifold 302 (e.g., a return manifold) for receiving heated fluid along a hot side of a liquid coolant circuit. The inlet manifold 302 receives fluid from two hoses 304, which can each return fluid from respective cabinets of electrical equipment (e.g., cabinets 10a and 10b shown in FIG. 1).

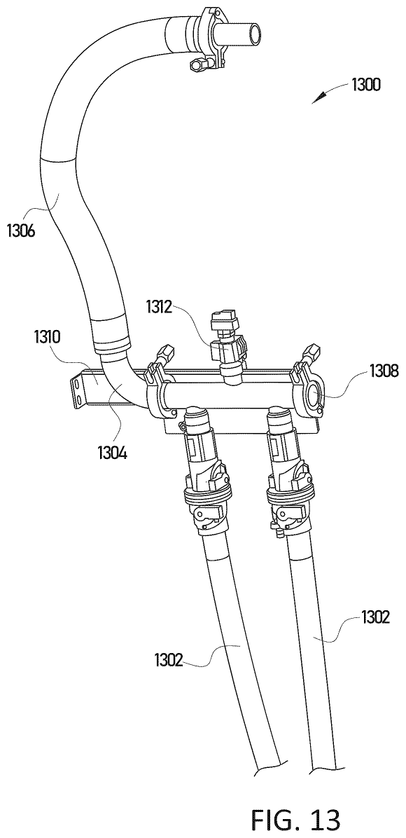

As described further with respect to the manifold 1300 shown in FIG. 13, the hoses 304 can be connected to the inlet manifold 302 at connection interfaces 306. The connection interfaces 306 can include shutoff valves 308 to block a flow of fluid from the corresponding hose 304 into the LACU 200. If one of the shutoff valves 308 is closed, the LACU 200 can receive heated coolant from only one cabinet, for example. The connection interfaces 306 can be quick disconnect fittings, as can allow for toolless connection of hoses 304 to the inlet manifold 302 to minimize the leakage of fluid when one of the hoses 304 is installed or disconnected. Other types of connection interfaces can also be used. For example, hoses of a hot side of a liquid cooling circuit can be connected to an inlet manifold using tri-clamp flanges. The inlet manifold 302 can also be configured to receive heated fluid from more than two cabinets, and can include three connection interfaces, or four connection interfaces, or five connection interface, or six connection interfaces, or more than six connection interfaces, etc., with each connection interface corresponding to hosing providing heated fluid to a liquid-to-air cooling unit from a corresponding cabinet of electrical cabinet.

As shown in FIG. 3, the inlet manifold 302 is positioned and configured to receive hosing 304 from a bottom of the cabinet 201 (e.g., in a bottom-feed configuration). However, (e.g., as further described with respect to manifold 1300), the manifold 302 can also be positioned and configured to receive hosing (e.g., hosing 304) in a top-feed configuration, with the connection interfaces 306 extending upwardly from the inlet manifold 302, among other possible configurations. For example, while the manifold 302 is shown to receive hosing 304 in a vertical direction, the manifold 302 could extend vertically within the cabinet 201 of the LACU 200 and can receive hosing from a direction that is orthogonal or substantially orthogonal to a vertical direction (e.g., from a horizontal direction). In some cases, the LACU 200 may not include an inlet manifold and hosing from electrical cabinets can connect directly to plumbing elements of the LACU 200.

The inlet manifold 302 is shown to include a sensor module 307 for measuring parameters of a fluid flowing into the LACU 200. The sensor module 307 can include a variety of different types of sensors, such as one or more sensors for measuring inlet temperature of a fluid entering the LACU 200. The sensor module 307 can also include additional temperature sensors as well as pressure sensors, flow rate sensors, and other types of sensors. Values from sensors of the sensor module 307 can be compared to values from other sensors along the liquid coolant circuit, as can facilitate a calculation of efficiency and cooling power provided by one or more components of LACU 200. As an example, an outlet manifold 344 can include a sensor module 345 which can be substantially identical to the sensor module 307, and a temperature value from a sensor of the sensor module 345 can be compared to a temperature value from a temperature sensor of the sensor module 307 to obtain a differential temperature between the inlet and outlet of the LACU 200. The LACU 200 can also determine a differential pressure or flow rate additionally or alternatively to the differential temperature measurement described, among other types of measurements.

The LACU 200 is further shown to include a liquid-to-air heat exchanger 202 (LAHX) positioned within the LACU 200. Liquid entering the LACU 200 can flow from the inlet manifold 302 to the LAHX 202. The LAHX 202 can include an inlet pipe 310 for receiving a heated fluid, and an outlet pipe 312 for outputting a cooled fluid from the LAHX 202. Additionally, the LAHX 202 can include a plurality of internal loops 314 to increase a length of a flow path of coolant through the LAHX 202 and maximize a surface area available for heat transfer between the fluid of the liquid coolant circuit and air. The LAHX 202 can also include a liquid port 316 along the outlet pipe 312 and a liquid port 318 along the inlet pipe 310.

The liquid ports 316, 318 can be used for injecting liquid into the LAHX 202 and removing air or liquid from the LAHX 202, and/or for regulating pressure along the liquid coolant circuit of the LAHX 202. For example, components of the LACU 200 can be “charged” (e.g., filled) with a coolant before installation or operation of the system. Additionally, components of the LACU 200 can be drained of fluid, including, for example, when the components are removed for servicing, or when a coolant is replaced. Either or both of the liquid ports 316, 318 can comprise quick disconnect fittings for selectively connecting fill lines, drain lines, or air bleed lines to the respective liquid ports 316, 318. As shown, the liquid ports 316, 318 ports can be connected to a liquid fill/drain line 320, which can be fluidly connected to the fill/drain port 225 described with respect to FIG. 2. However, in some cases, there is no piping or hosing connected to the ports 316, 318 in normal operation of the LACU 200.

In some cases, air within a liquid coolant circuit can cause damage to components along the liquid cooling circuit, including, for example, to pumps of a liquid cooling circuit, or to electronic components to be cooled. Air within a liquid cooling circuit can also reduce a total cooling efficiency of the system, so that greater power is required to cool electronic components. Systems can therefore be provided for a liquid-to-air cooling unit to remove air (e.g., bleed air) from piping of a liquid cooling circuit. Since air is less dense than water, air bubbles will tend to rise to a highest point along a liquid flow path of a liquid cooling circuit, and therefore, air bleed valves can be provided at points of the liquid flow path of a liquid cooling circuit that are elevated (e.g., vertically higher) relative to other portions of the piping or plumbing elements.

As shown in FIG. 3, the liquid ports 316, 318 can be located at or near a top of the respective pipes 310, 312. Flow of fluid from one or more of the ports 316, 318 can be redirected to an air bleed valve 322. In normal operation of the LACU 200, the air bleed valve 322 can be fluidly isolated from the liquid cooling circuit. However, when an operator is performing an air bleed operation (e.g., when initially charging all or a portion of the LACU 200 with a fluid), the air bleed valve 322 can be fluidly connected to either or both of the ports 316, 318 to bleed air therefrom. The air bleed valve 322 can include a connection hose 324 which can be connected to either or both of liquid ports 316, 318 to bleed air from the liquid cooling circuit at either respective location. The air bleed valve 322 can be secured to the cabinet with a mounting bracket 323.

In some cases, it can be useful to include components within the LACU 200 to regulate or maintain a set pressure within the LACU 200, or to prevent a pressure from exceeding a certain value. For example, if a heat of a fluid in a liquid cooling circuit increases, the fluid within the circuit can expand, which can increase a pressure along all or a portion of the liquid cooling circuit. Accordingly, as illustrated, the LACU 200 can include an expansion tank 326. The expansion tank 326 can be in fluid communication with the liquid cooling circuit and can receive fluid from the liquid cooling circuit when a pressure in the liquid cooling circuit exceeds a pressure charge of the expansion tank 326.

In the example shown, the expansion tank 326 is fluidly positioned along a hot side of the liquid cooling circuit and is connected to the inlet pipe 310 of the LAHX 202 at a liquid port 328. The liquid port 328 can be positioned along the inlet pipe 310 to provide pressure regulation on the hot side of the liquid cooling circuit (e.g., where liquid of the liquid cooling circuit is more prone to expansion due to an increased heat relative to other portions of the cooling unit 200). In some examples, the expansion tank 326 can be positioned at other points along the liquid cooling circuit. For example, the expansion tank 326 can be installed downstream of the LAHX 202, or downstream of the RPU 204. Also, the LACU 200 in some examples may not include the expansion tank 326, or the LACU 200 can include multiple expansion tanks.

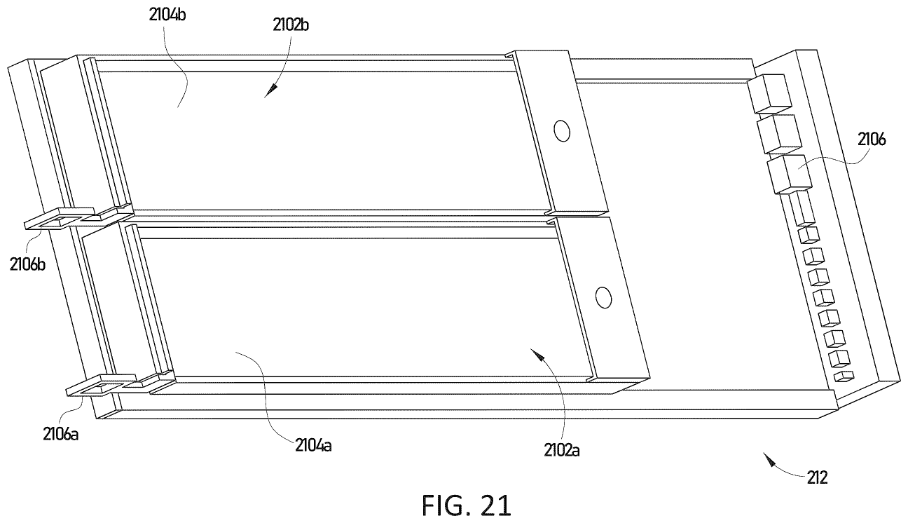

As shown in FIG. 3, the outlet pipe 312 of the LAHX 202 can be fluidly connected to the RPU 204. For example, an angled elbow connector 330 can be positioned at an outlet end of the outlet pipe 312 and can direct fluid flow generally towards an inlet port 332 of the RPU 204. The angled elbow connector 330 can ensure a smooth (e.g., as opposed to turbulent) flow of fluid into the RPU 204. Fluid can be pumped through the RPU 204, as further described below, and may exit the RPU 204 at an output port 334. Flexible hosing 336 can be used to fluidly connect the RPU 204 to the liquid cooling circuit, and the flexible hosing 336 can be connected to the ports 332, 334, and other plumbing components (e.g., the outlet pipe 312 or the elbow connect 330) through clamping systems 338 (e.g., tri-clamp flange systems). In some implementations, the LACU 200 may not include an RPU or pumping units and may instead rely on a pressure provided from a facility (e.g., as illustrated for example in the schematic of FIG. 21).

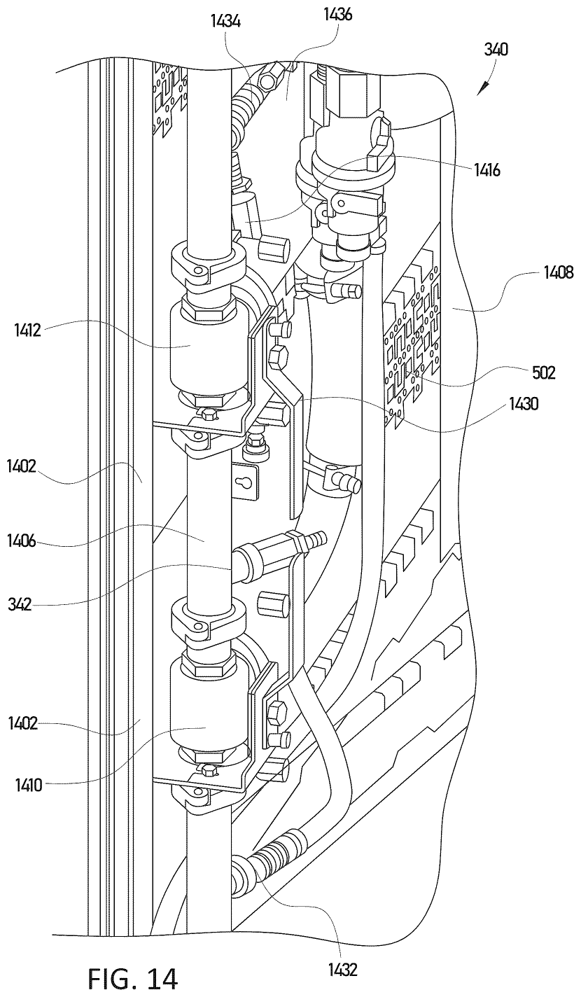

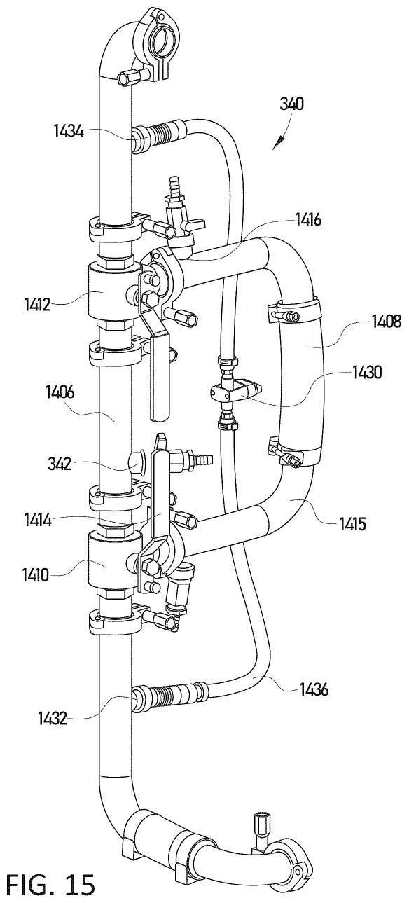

In The LACU 200 is also shown to include a filter assembly 340. The filter assembly 340 can provide filtration for fluid circulating in the LACU 200 to remove impurities and particulate matter that can damage plumbing elements and reduce cooling efficiency of the LACU 200. The filter assembly can be implemented using a variety of suitable filtration components, such as a fluid filter 342 as shown in FIG. 3, and can be positioned immediately downstream of the RPU 204 in some implementations. The filter assembly 340 is discussed in more detail below with respect to FIGS. 14 and 15. The LACU 200 is also shown to include an outlet manifold 344 for fluid of the liquid cooling circuit to exit the LACU 200. The fluid exiting the outlet manifold 344 can be at a lower temperature than the fluid flowing into the LACU 200 at the inlet manifold 302. The outlet manifold can be similar to the inlet manifold 302 as described above, for example, as well as the manifold 1300 shown and described below with respect to FIG. 13.

The LACU 200 is also shown to include power inlets 350 to receive respective power connections from a data center. Connections for electricity can be provided within a data center to power electrical elements within cabinets installed in the data center. In some cases, redundant power supplies can be provided for a cabinet to ensure continued operation of the electrical components within a cabinet on failure of a single power supply. The power inlets 350 can be in direct electrical communication with the power supply unit 226, and the power supply modules 230 (as shown in FIG. 2) can transform the received power to have desired characteristics (e.g., to convert from AC to DC, to produce a desired output voltage or current, etc.). In some cases, the power inlets 350 can receive a three-phase AC power signal. The LACU 200 can operate with power from only one of the power inlets 350, and the opposite inlet can be used when there is a failure in the power source connected to the primary power inlet 350, or when the connection to the primary power inlet 350 is removed.

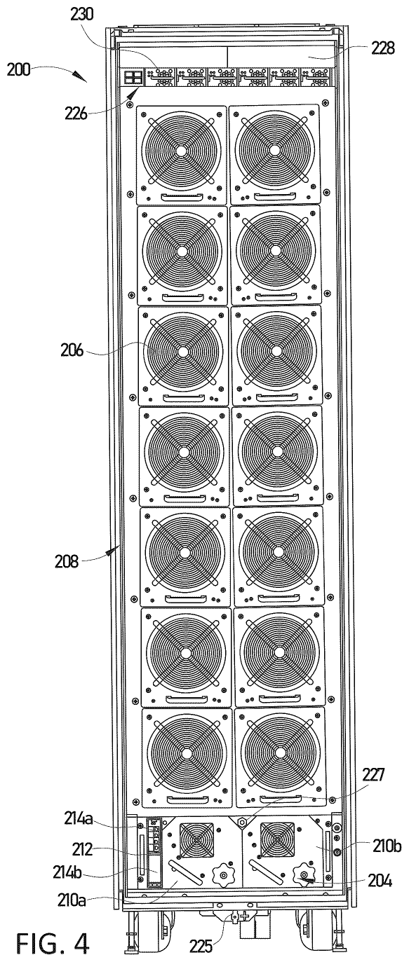

Referring to FIG. 4, a front elevation view of the example LACU 200 is shown, in accordance with some aspects of the disclosure. From the view shown in FIG. 4, six power supply modules 230 can be seen. In some cases, a first one of the power inlets 350 provides powers to a first plurality of power supply modules (e.g., three out of six of the power supply modules 230 illustrated in FIGS. 2 and 4) and a second one of the power inlets 350 provides power to a second plurality of power supply modules (e.g., another three of the six power supply modules 230 shown in FIGS. 2 and 4). In some cases, an operator of the LACU 200 can set a mode in which to operate the LACU 200, which can include a power supply configuration including whether the power inlets 350 are used in a primary/backup configuration, whether the power inlets 350 each power a corresponding one or more power supply modules 230, or other configurable settings of the power supply unit 226.

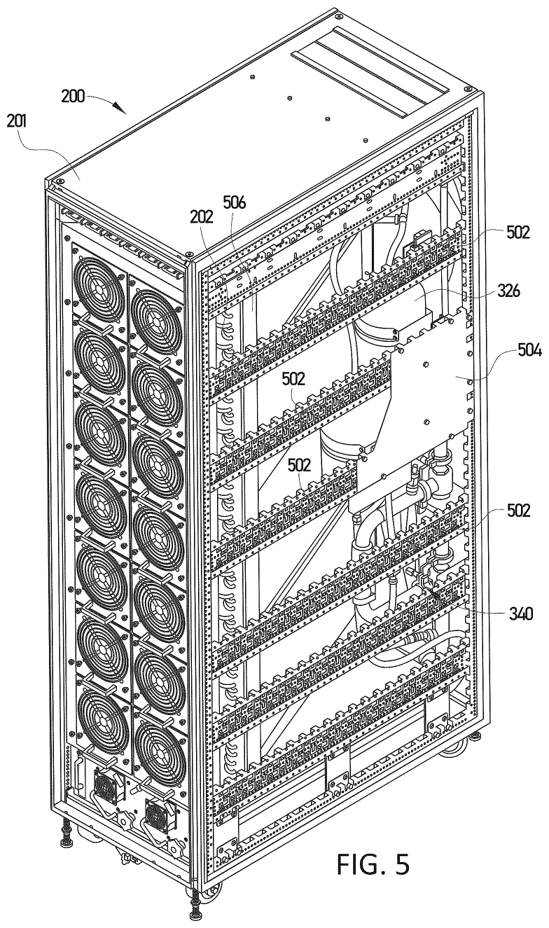

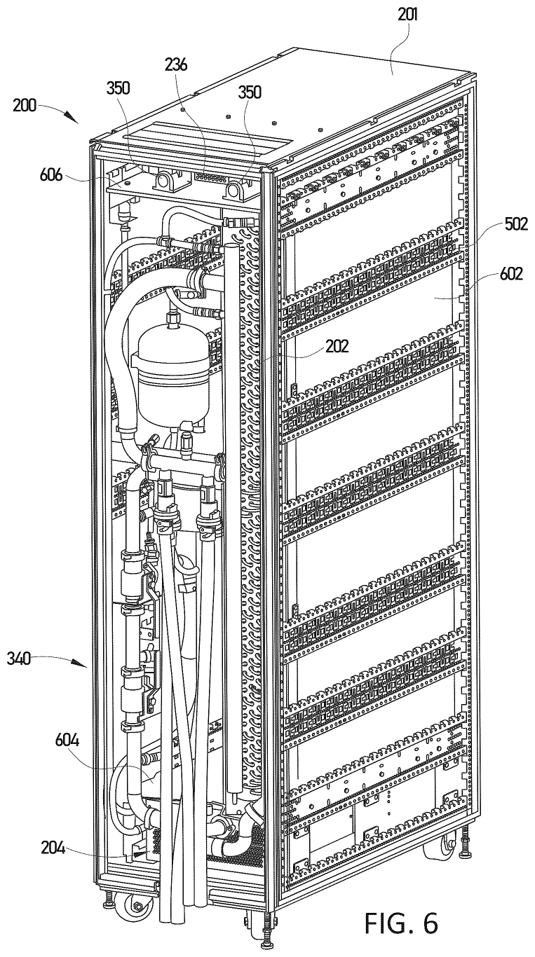

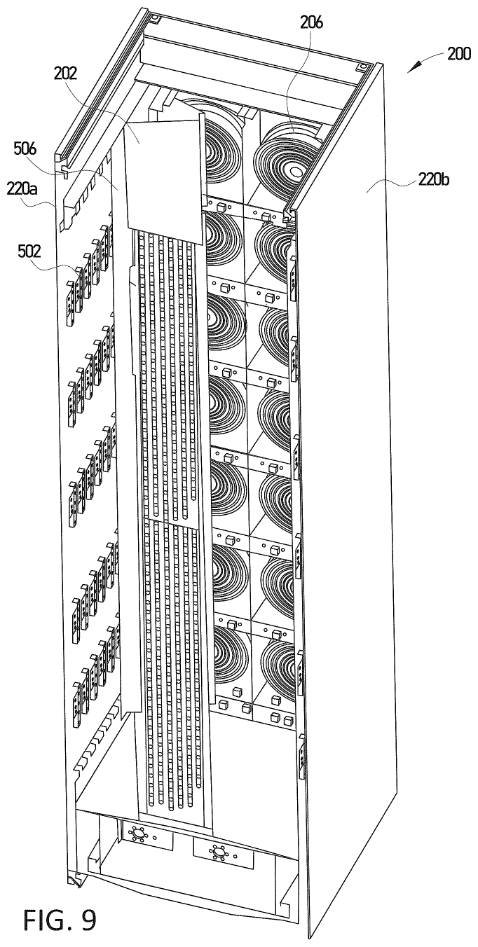

Referring to FIG. 5, a front, right isometric view of the LACU 200 is shown, in accordance with some aspects of the disclosure. Referring to FIG. 6, a rear, left isometric view of the LACU 200 is shown, in accordance with some aspects of the disclosure. From the view shown in FIG. 5 and in FIG. 6, the LACU 200 can be seen with the side panels 220 removed to illustrate structural components of the cabinet 201. As shown in FIG. 5, a plurality of mounting bars 502 can be provided that can span the cabinet 201 from the front to the rear of the cabinet 201. The mounting bars 502 can be spaced apart from each other in a vertical direction. As shown, the plumbing components of the LACU 200 (e.g., the LAHX 202, filter assembly 340, and expansion tanks 326) can be secured to the cabinet 201 at one or more of the mounting bars 502. For example, an expansion tank mounting plate 504 is shown to be mounted to the mounting bars 502 of the cabinet 201. The expansion tank mounting plate 504 can be secured to two contiguous mounting bars 502 to provide stability to the system. Correspondingly, a filter mounting plate can be provided to mount the filter assembly 340 to the mounting bars 502 of the system. A vertical bracket 506 can be secured to the mounting bars 502 and to secure the LAHX 202 to the cabinet 201, as further described below with respect to FIG. 9.

As shown in FIG. 6, the LACU 200 can include a baffle plate 602 provided on at least one side of the cabinet 201. The baffle plate 602 can direct air flow to maximize heat transfer efficiency across the LAHX 202. The baffle plate 602 can prevent air flow out of the side of the cabinet 201 before the air flow traverses the LAHX 202, thus increasing the cooling efficiency of the system by maximizing the flow of air through the LAHX 202. One or more additional baffle plates can be provided within the LACU 200, such as on either side of the LAHX 202. For example, it can be advantageous to maximize the flow of cool air across the LAHX 202 and less important to control the flow of air once it has transferred heat from a liquid within the LAHX 202. Thus, a direction of air flow across the heat exchanger can be relevant to determining a location or number of baffle plates of a liquid-to-air cooling unit.

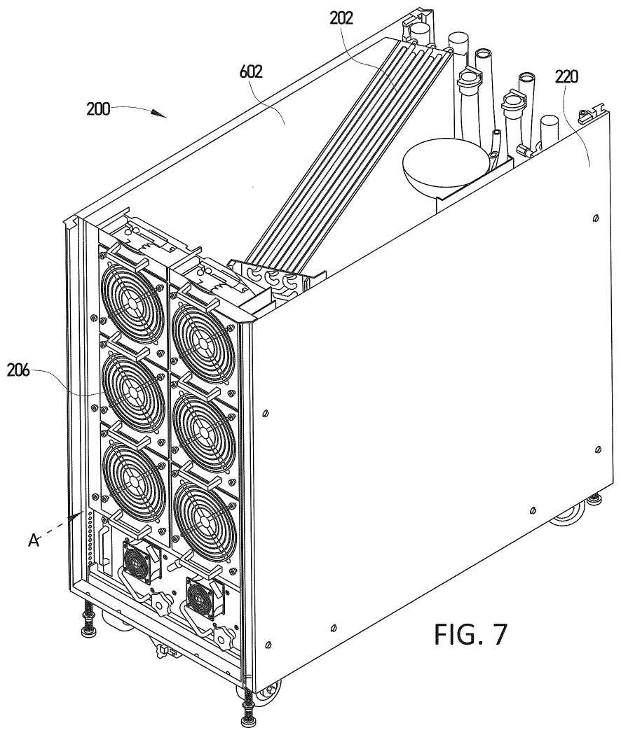

Referring to FIG. 7, a section view of the example LAHX 202 of the example LACU 200 is shown, in accordance with some aspects of the disclosure. The view shown in FIG. 7 is generally a section view where the LAHX 202 is provided at an oblique angle relative to the side walls of the LACU 200. The fans 206 of the LACU 200 can operate to produce air flow in the “A” direction as shown in FIG. 7 (i.e., from the front of the LACU 200 to the rear of the LACU 200). The baffle plate 602 and the LAHX 202 can define a flow path of the air, with the baffle plate 602 preventing air flow out of the side of the cabinet 201. Substantially all air flow can be directed across a surface of the LAHX 202 to maximize a rate of heat transfer and an efficiency of a heat transfer (e.g., to reduce a power required for the fans 206 to produce a given heat transfer rate). In other implementations, the fans 206 can direct air flow in a direction opposite the direction A (e.g., from a rear to a front of the LACU 200). In such implementations, it can be advantageous to position the baffle plate 602 along the opposite lateral side of the LACU 200 to direct a maximal volume of cool air across the LAHX 202. In some cases, the side panels 220 can function as a baffle for air flow such that the baffle plate 602 is not necessarily included.

Referring to FIG. 8, a top view of the example LACU 200 illustrating the LAHX 202 is shown, in accordance with some aspects of the disclosure. The LACU 200 can be sized and positioned to maximize air flow through the LAHX 202. For example, a rate of heat transfer from a liquid to an air along the LAHX 202 can be increased by increasing a surface area of LAHX 202. by maximizing the surface area exposed to air flow by positioning the LAHX 202 at an oblique angle relative to the direction of air flow. The surface area of the LAHX 202 in contrast can be minimal when a heat exchange surface of the LAHX 202 is positioned perpendicular to the direction of air flow. As shown in FIG. 8, the LAHX 202 is positioned along an axis “B”. The axis B can be positioned at an oblique angle “C” relative to a first side panel 220a at a first lateral side of the LACU 200. In the example illustrated in FIG. 8, the angle C is about 22.5 degrees, however the angle C can vary from between 20-30 degrees, between about 30-40 degrees, between about 40-50 degrees, or up to 90 degrees, depending on the application. In some cases, the angle C can decrease with an increased depth of the LACU 200. As also shown in FIG. 6, for example, the LAHX 202 can span a height within the cabinet 201, between a plate 604 on a top of the RPU 204, and a plate 606 at a lower end of the power supply unit 236. However, the height of the LAHX 202 can vary depending on the application. For example, the height of the LAHX 202 can vary based on the height of the RPU 204.

Referring to FIG. 9, a section view of the example LACU 200 including the mounting bracket 506 is shown, in accordance with some aspects of the disclosure. The mounting bracket 506 can be used to secure the LAHX 202 within the cabinet 201. The mounting bracket 506 can be made of different materials such as sheet metal and can be bent to accommodate different mounting angles (e.g., the angle C shown in FIG. 8) of the LAHX 202 within the cabinet 201. Also, more than one mounting bracket can be used. For example, referring back to FIG. 8, a first mounting bracket 506a is shown to secure the LAHX 202 to the cabinet 201 at a lateral side of the LACU 200 including a first lateral side panel 220a, and a second mounting bracket 506b is shown to secure the LAHX 202 to the cabinet 201 at a second lateral side of the LACU 200 corresponding to a second lateral side panel 220b. Depending on the width of the LAHX 202, the LAHX 202 can be mounted at different locations along respective lateral sides, and the mounting brackets 506a, 506b can deform to secure the LAHX 202 at a desired angle within the cabinet 201.

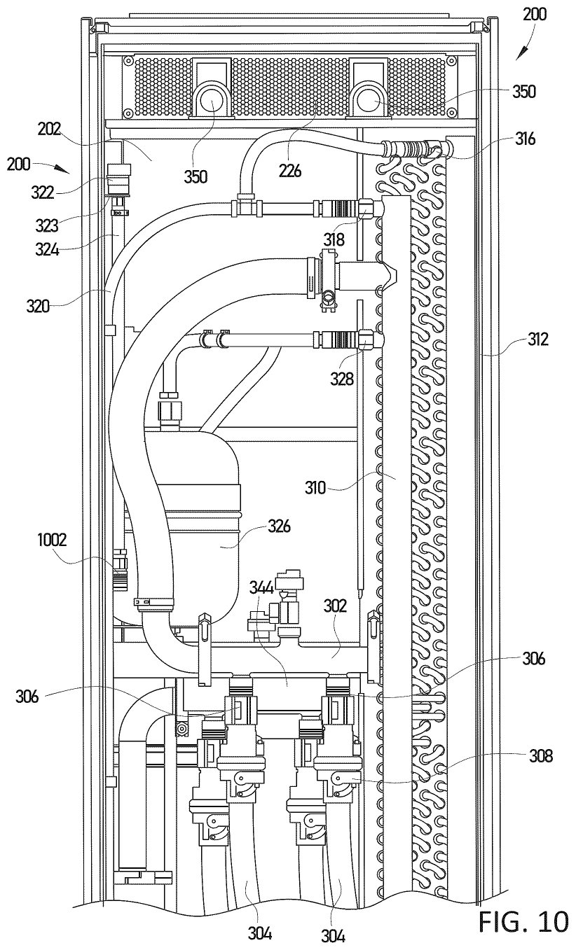

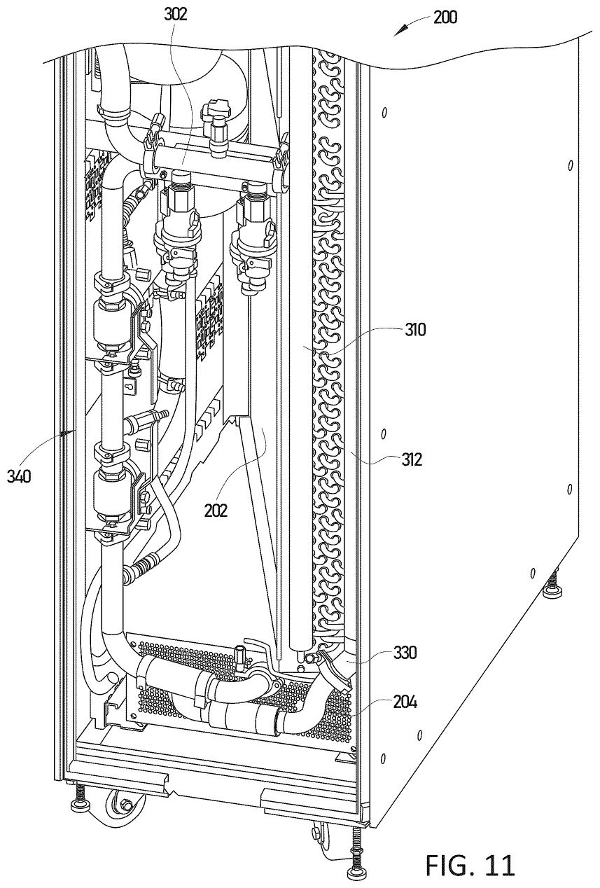

Referring to FIG. 10, a partial top view showing plumbing components of the example LACU 200 is shown, in accordance with some aspects of the disclosure. From the view shown in FIG. 10, one can see the air bleed valve 322 which can be fluidly isolated from the fluid cooling circuit during normal operation of the LACU 200. As shown, the air bleed valve 322 can be secured to the cabinet 201 (e.g., secured to a mounting bar 502 as shown in FIG. 5) via a mounting bracket 323. Also shown, the hose 324 can extend downward (e.g., can hang from the bracket 323, and can include a quick connect fitting 1002 at the end of the hose). The quick connect fitting 1002 can be a female quick connect fitting and can be connected to either of the liquid ports 316, 318. For example, when bleeding air along the liquid cooling circuit, one or more of the connections from fill/drain hose 320 can be disconnected from the respective liquid port 316, 318, and the quick connect fitting 1002 of the air bleed valve 322 can be connected to the respective liquid port 316, 318 to bleed air therefrom. In some cases, the air bleed valve 322 can be fluidly connected to the liquid cooling circuit during normal operation thereof and can operate to continually bleed air from the hose 324. Referring to FIG. 11, a partial bottom view showing plumbing components of the example LACU 200 is shown, in accordance with some aspects of the disclosure. From the bottom view of FIG. 11, further plumbing components of the LACU 200 such as the filter assembly 340 can be seen in more detail.

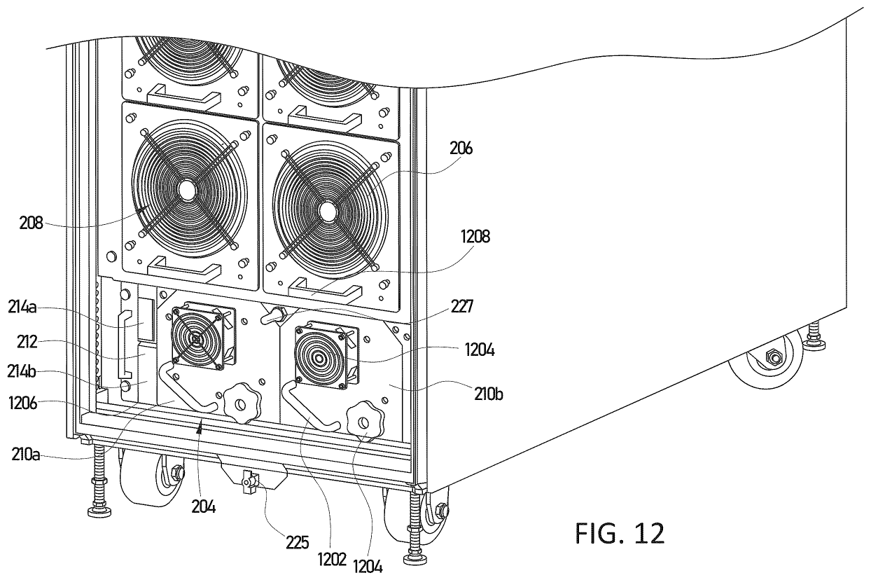

Referring to FIG. 12, a partial bottom view showing the pump cassettes 210a, 210b of the example LACU 200 is shown, in accordance with some aspects of the disclosure. As noted, the pump cassettes 210a, 210b can be redundant and hot-swappable, which can minimize a disruption to the operation of the LACU 200 when a single component fails. Accordingly, the pump cassettes 210a, 210b can include features to facilitate insertion and removal in the event of failure or other circumstances. As shown, each of the pump cassettes 210a, 210b includes a cassette handle 1202 to provide an operator a gripping point for removing or installing the respective pump cassette into the RPU 204. In some examples, the pump cassettes 210a, 210b can include more than one handle to provide gripping locations for two hands of an operator, for example. In some cases, the pump cassettes 210a, 210b can include features for locking the cassette in place or unlocking the cassette to enable removal. As further shown in FIG. 12, each of the pump cassettes 210a, 210b includes a locking knob 1204, which, when rotated in a first direction (e.g., clockwise), can engage a locking mechanism of the RPU 204 to lock the respective cassette 210a, 210b in place within the RPU 204. The locking knob 1204 can be rotated in a second direction opposite the first direction (e.g., counterclockwise) to disengage the locking mechanism and allow translation of the pump cassettes 210a, 210b relative to the RPU 204.

As further shown in FIG. 12, the fans 206 of the LACU 200 can include fan handles 1208 to provide a gripping location to allow an operator to remove the respective fan 206. Also, the hot swappable control modules 214a, 214b can include cassette support features to facilitate removal and installation of the respective control modules 214a, 214b. As shown, each control module 214a, 214b can include an engagement tab 1206. The engagement tab 1206 can provide a gripping location (e.g., a handle) for an operator to install or remove the respective control module 214a, 214b from the RPU 204. Additionally, the engagement tab 1206 can include retention features to secure the respective control module 214a, 214b in place within the RPU 204. For example, protrusions of the grasping tab can snap ably engage geometries of the RPU 204 to retain the control module 214a, 214b in place once inserted. To disengage the protrusions from the RPU 204 and allow removal of the respective control module 214a, 214b, an operator can displace the respective engagement tab 1206 in a vertical direction (e.g., along a height of the LACU 200), and can subsequently pull the engagement tab 1210 to remove the control module 214a, 214b. Other retention mechanisms can also be used to retain the control modules 214a, 214b in place.

Referring to FIG. 13, an isometric view of an example manifold 1300 that can be used with the example LACU 200 is shown, in accordance with some aspects of the disclosure. The manifold 1300 provides an example implementation of the inlet manifold 302 and/or the outlet manifold 344 (supply or return manifold) as discussed above. As shown in FIG. 13, the manifold 1300 is oriented in a downward direction, relative to the cabinet 201, as may allow hosing 1302 from the electrical equipment cabinets to be routed through a cutout in the bottom of the cabinet, or out through the cutout 224 in the side panel 220, as illustrated in FIG. 2. As shown, an elbow connection 1304 extends from the left of the manifold 1300. For an inlet manifold (e.g., manifold 302 illustrated in FIG. 3), the elbow connection 1304 couples a hosing 1306 to the manifold that routes the coolant to the heat exchanger (e.g., the LAHX 202, illustrated in FIG. 3). When the manifold 1300 is an outlet (e.g., a supply) manifold, the elbow connection 1304 and hosing 1306 fluidly connect the manifold 1300 to a filter assembly of a liquid-to-air cooling unit (e.g., filer assembly 340 shown in FIG. 3).

On the right side of the illustrated manifold 1300, a cap 1308 is provided to prevent fluid flow out of the right end of the manifold 1300. Though the manifold 1300 is shown in an orientation with the hosing 1302 extending downwardly (e.g., in a bottom feed configuration), the manifold 1300 may be positioned so that the hosing 1302 can extend upwardly from the manifold. To reverse the orientation, the manifold 1300 can be removed from the bracket 1310 securing the manifold 1300 to a cabinet (e.g., the cabinet 201 shown in FIG. 3). The manifold 1300 may be rotated and reinstalled in the bracket 1310, with the side of the manifold 1300 previously shown at the right being positioned at the left, and the side of the manifold shown on the left being reinstalled on the right. So positioned, the cap 1308 can be repositioned to the opposite of the manifold 1300, and the elbow connection 1304 can be repositioned to the opposite side of the manifold. The hosing 304 can then extend downwardly, and the hosing 1302 can extend upwardly relative to a cabinet (e.g., the hosing can be in a top feed configuration for the cabinet 201 shown in FIG. 2).

It can be advantageous to measure one or more properties of fluid at the manifold 1300. For example, a first temperature at the inlet manifold 302 can indicate a heat of fluid returning from electrical equipment, and a temperature measured at the outlet manifold 344 can indicate a heat of fluid being supplied to cool the electrical equipment. A difference between the first temperature and the second temperature can indicate a total cooling efficiency of the LACU 200 and can be provided to control systems of the unit (e.g., as described below) to allow components of the cooling unit to be controlled to achieve a desired value (e.g., a set point) for a differential temperature between the inlet and the outlet. As illustrated, then, the manifold 1300 can include a sensor module 1312 (e.g., similar to or identical to the sensor modules 307, 345 shown in FIG. 3) positioned along the flow path of a fluid in the liquid cooling circuit. In some examples, the sensor module 1312 can include a temperature sensor. In some cases, the sensor module 1312 can additionally or alternatively measure other properties of a fluid in the liquid cooling circuit, including, for example, a flow rate, a pressure, a density, a chemical composition, etc. Sensors can be provided along different points of a flow path of fluid in a liquid cooling circuit and can be inputs or target values for a control system of the LACU 200.

Referring to FIG. 14, a first isometric view of the filter assembly 340 of the example LACU 200 is shown, in accordance with some aspects of the disclosure. Referring to FIG. 15, a second isometric view of the filter assembly 340 of the example LACU 200 is shown, in accordance with some aspects of the disclosure. The filter assembly 340 can include features for providing redundancy of components of the filter assembly 340 and indicating a need for servicing of components of the filter assembly 340. As shown in FIG. 14, the filter assembly 340 can be secured to the cabinet 201 with sheet metal brackets 1402 fixed to the mounting bars 502 of the cabinet 201. As shown, piping of the filter assembly 340 can define a primary flow path 1406 and a secondary flow path 1408. An inlet valve 1410 can define an entry for each of the primary flow path 1406 and the secondary flow path 1408. An outlet valve 1412 can define an exit for fluid from each of the primary flow path 1406 and the secondary flow path 1408.

The valves 1410, 1412 can include handles 1414 to allow the valves to be moved between a respective first position, in which flow is allowed exclusively through the primary flow path 1406, a second position, in which fluid flow is allowed exclusively through the secondary flow path 1408, and a third position, in which fluid flow is not allowed through either of the primary or secondary flow paths 1406, 1408. Either or both of the valves 1410, 1412 can be electronically controlled (e.g., through linear actuators, servo motors, etc.) and may or may not require manual engagement. The valves 1410, 1412 can be ball valves or any other type of valves with the capability of routing fluid flow as described. In some cases, as shown, the primary flow path 1406 does not include bends (e.g., fluid flows in a straight line from valve 1410 to valve 1412), and the secondary flow path 1408 includes one or more bends 1415 in piping thereof. Thus, the secondary flow path 1408 can introduce a greater pressure drop for fluid when compared with the primary flow path 1406.

As further illustrated in FIGS. 14 and 15, the primary flow path 1406 can include a primary filter 342, and the secondary flow path can include a secondary fluid filter 1416 for removing particulate matter and impurities from a fluid along either of the respective flow paths 1406, 1408. In some cases, particulate matter can build up within one of the respective filters 342, 1416, and the filter may then be removed for servicing. To service one of the filters 342, 1416, an operator can move the valves (e.g., via the handle 1414) to a position to allow fluid flow through the flow path 1406, 1408 not including the filter to be serviced. Fluid can then flow through the other filter 342, 1416 while the filter is being serviced, and thus a maintenance to a filter does not introduce a down time for the LACU 200.

The filter assembly 340 can include features for detecting a state of the filters 342, 1416 (e.g., for indicating a need for servicing). For example, when particulate matter builds up within the filters 342, 1416, flow of fluid through the filters 342, 1416 can be restricted, and a pressure upstream of the filters 342, 1416 can be greater than a pressure downstream of the filters 342, 1416. Thus, measuring a pressure upstream and downstream of the filters 342, 1416 can allow an operator to determine a pressure drop across the filters 342, 1416, and, when the pressure drop exceeds a threshold value, this can indicate a need to service the filters 342, 1416. Accordingly, a differential pressure sensor 1430 can be provided along the fluid coolant circuit.

The differential pressure sensor 1430 can measure a pressure difference between a fluid at an upstream port 1432 and a downstream port 1434. The upstream port 1432 can be located upstream of both of the primary flow path 1406 and the secondary flow path 1408, and the downstream port 1434 can be located downstream of both of the primary flow path 1406 and the secondary flow path 1408. The hosing 1436 can be connected to each of the upstream port 1432 and the downstream port 1434 with quick disconnect fittings to facilitate a servicing and replacement of the differential pressure sensor 1430. Thus, the differential pressure sensor 1430 can be removed and reinstalled without the use of tools, and without providing a disruption or interruption to the system operation. The differential pressure sensor 1430 can be operatively connected to a control system of the LACU 200 (e.g., such as discussed below), and the control system can provide an indication to an operator (e.g., an alert, a message, a visual indication, etc.) that one or more of the filters 342, 1416 require servicing.

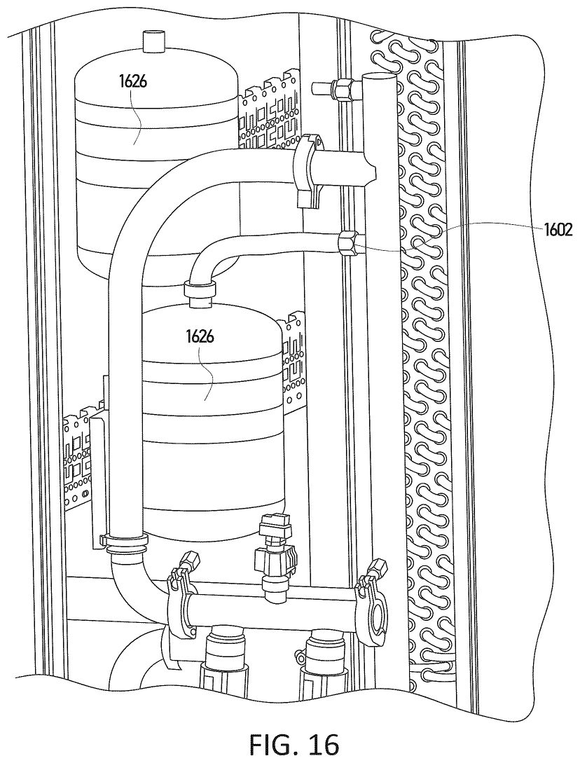

Referring to FIG. 16, a rear isometric view showing example expansion tanks 1626 of the example LACU 200 is shown, in accordance with some aspects of the disclosure. The expansion tanks 1626 provide example implementations of the expansion tank 326 as discussed above. The expansion tanks 1626 can each be charged for a rated pressure (e.g., 1 bar), and can be connected to plumbing of the LACU 200 with quick disconnect fittings. Thus, one of the expansion tanks 1626 can be removed for performance of servicing or replacement (e.g., by a toolless disconnection), and the other expansion tank 1626 can continue to regulate a pressure within the LACU 200. The LACU 200 can include any number of expansion tanks, such as more than two expansion tanks, or only one expansion tank, or no expansion tanks. In some cases, only one of the expansion tanks 1626 is connected to the liquid cooling circuit at a given time, and an operator can manually connect a backup expansion tank 1626 to the liquid coolant circuit (e.g., at liquid port 1602), when the connection to the other expansion tank 1626 is removed.

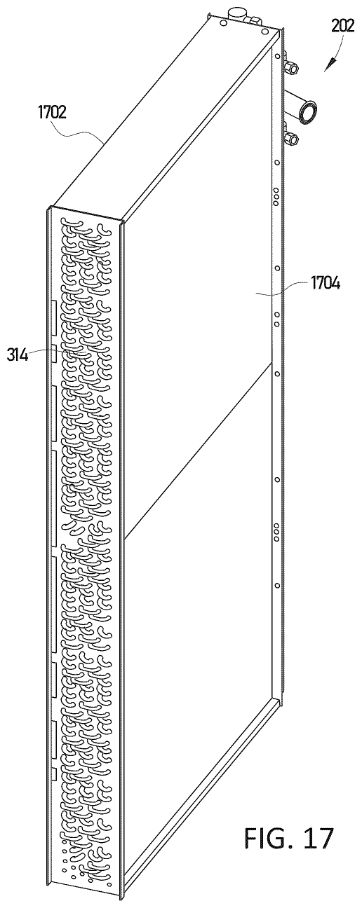

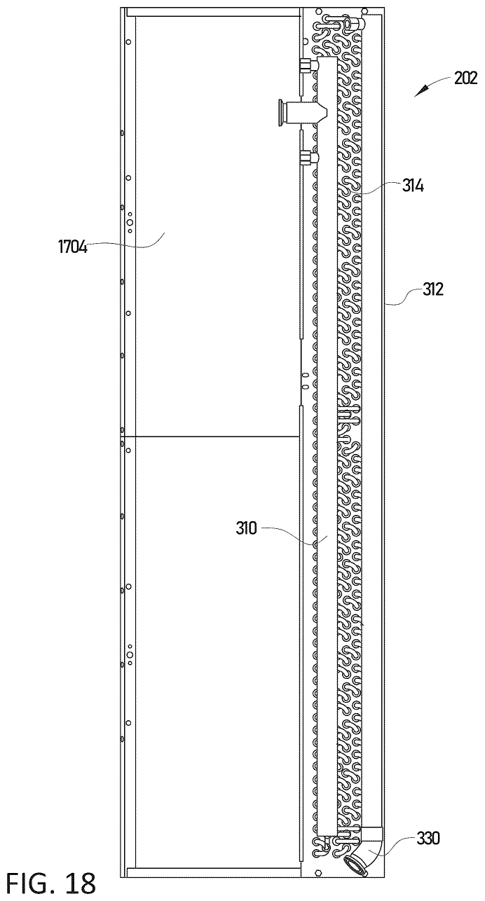

Referring to FIG. 17, a first isometric view of the LAHX 202 of the example LACU 200 is shown, in accordance with some aspects of the disclosure. Referring to FIG. 18, a second isometric view of the LAHX 202 of the example LACU 200 is shown, in accordance with some aspects of the disclosure. As shown, the LAHX 202 includes a front surface 1702 and rear surface 1704, which can each define a rectangular surface which, when installed, can span a width of the LACU 200, as described above. The area of these surfaces 1702, 1704 can provide an interface at which heat can be transferred from the liquid coils 314 within the LAHX 202 to the surrounding air. FIGS. 17 and 18 illustrate different portions of the liquid cooling coils 314 protruding out from sides of the LAHX 202, and the combination of the total length of the coils 314, and the surface area of the coils 314 exposed to the surrounding air can maximize the cooling efficiency of the LAHX 202.

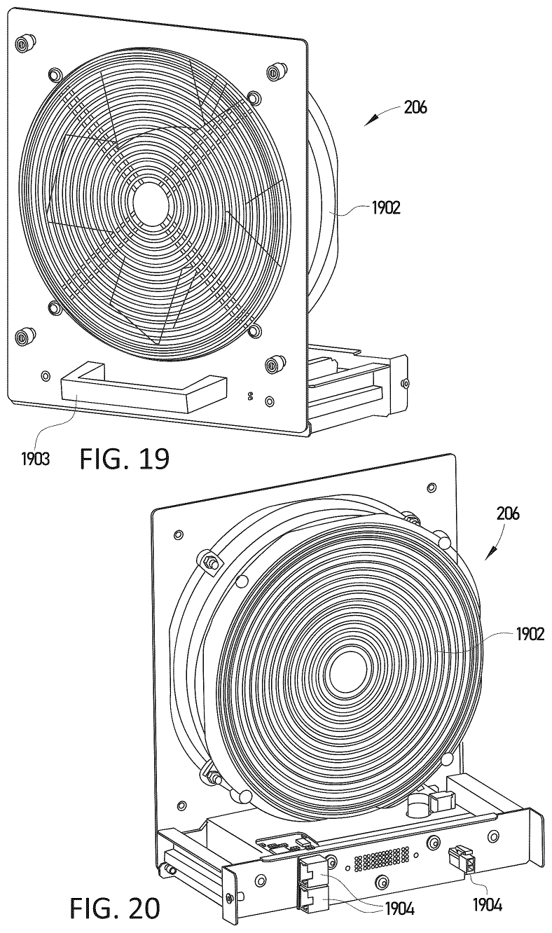

Referring to FIG. 19, a front view of one of the fans 206 of the example LACU 200 is shown, in accordance with some aspects of the disclosure. Referring to FIG. 20, a rear view of one of the fans 206 of the example LACU 200 is shown, in accordance with some aspects of the disclosure. As shown in FIG. 19 and FIG. 20, the fans 206 can include an impeller 1902 mounted on a back side of the fans 206. The fans 206 can also include a handle 1903 (e.g., similar to the handle 1208 shown in FIG. 12) to facilitate insertion and removal of the fans 206 into and from the LACU 200. The fans 206 can further include one or more blind mate connectors 1904 to engage corresponding electrical connections and interfaces of the LACU 200. The fans 206 can be hot swappable fan modules and can be replaced during operation of the LACU 200. In some cases, the fans 206 includes sensors for sensing properties of an air flowing through the fans 206, or of ambient air surrounding the fans 206. For example, the fans 206 can include flow sensors to measure a rate of flow of air, temperature sensors to measure air temperature, and/or humidity sensors. Additionally, the fans 206 can include a fan controller to control operational aspects of the fans 206 (e.g., fan speed). The controller can receive instructions from a main controller of the LACU 200 (e.g., over a wired or wireless connection, Modbus, Ethernet, etc.). When the fan controller is not connected to the main controller, the fan controller can operate the fan according to preprogrammed algorithms to retain a speed, increase a speed, decrease a speed, or stop the impeller of the fan, for example.

Referring to FIG. 21, an isometric view of the control unit 212 of the LACU 200 is shown, in accordance with some aspects of the disclosure. As shown, the control unit 212 can include two compartments 2102a, 2102b for housing two separate control module 2104a, 2104b (e.g., similar to or identical to control modules 214a, 214b shown in FIGS. 2 and 12), which can alternately be referred to as controller cartridges. The control unit 212 can be sized and configured to be received into a slot of the RPU 204, for example. The control modules 2104a, 2104b can include blind mate connecters that can engage with corresponding electrical connections of the RPU 204 when the control unit 212 is installed therein. In some examples, the control modules 2104a, 2104b are identical, and can provide identical controls for the LACU 200. Various electronic components of the LACU 200 (e.g., fans 206 and RPU 204) can be controlled by one or both of the control modules 2104a, 2104b.

In some examples, the control modules 2104a, 2104b include failover capabilities so that when a primary one of the control modules 2104a, 2104b is removed from the control unit 212, the other one of the control modules 2104a, 2104b assumes control of electrical components of the LACU 200. In some examples, a state of the LACU 200 can be continually synced between the control modules 2104a, 2104b to facilitate failover when one of the control modules 2104a, 2104b fails or is replaced. Each of the control modules 2104a, 2104b can provide a different mode of operation or different control logic for the LACU 200, and the provision of two controller units in this manner can allow a user to selectively choose a particular control module 2104a, 2104b to use when the control unit 212 is provided in the LACU 200. Alternatively, one controller of the control unit 212 may provide a base functionality with the controller in the other compartment providing extension of functionalities for specific applications of the LACU 200. As shown, an interface board 2106 for inputs and outputs can also be provided in the control unit 212 for forming various electrical connections within the LACU 200.

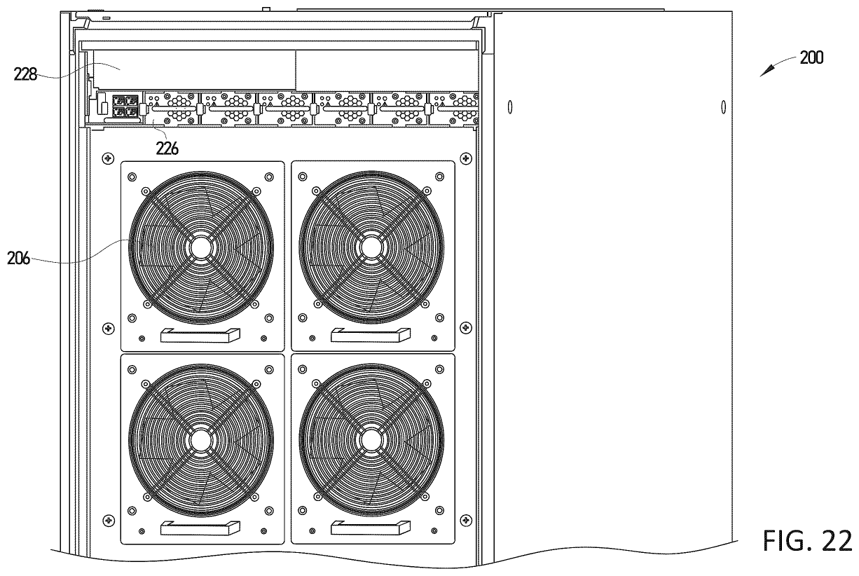

Referring to FIG. 22, an isometric view of the power supply unit 226 of the LACU 200 is shown, in accordance with some aspects of the disclosure. Referring to FIG. 23, another isometric view of the power supply unit 226 of the LACU 200 is shown, in accordance with some aspects of the disclosure. The power supply unit 226 can provide power to electronic components of the LACU 200 at specific voltages, and with the appropriate power characteristics (e.g., frequency, current, voltage, etc.). FIG. 22 illustrates the power supply unit 226 installed in a top of the LACU 200, and FIG. 23 illustrates the power supply unit 226 isolated from the LACU 200. The power supply unit 226 can include features and systems for providing redundancy and resiliency to the LACU 200, or other cabinets with electronic equipment which may be powered thereby. For example, as shown, the power supply unit 226 includes a plurality (e.g., 6) of hot-swappable power supply modules 230a, 230b, 230c, 230d, 230e, 230f. In some cases, the power supply modules 230 can be 3 kilowatt (KW) power supply modules. In other cases, the power supply modules 230 can provide other amounts of power, such as about 1 kW, 2 kW, 4 kW, or 5 kW of power.

In some examples, the LACU 200 can operate with a threshold number of power supply modules in operation. For example, the LACU 200 can require a minimum of one operational power supply module, a minimum of two operational power supply modules, a minimum of three operational supply modules, a minimum of four operational supply modules, a minimum of five operational supply modules, etc. Thus, the LACU 200 may be able to withstand the loss of one or more of the power supply modules 230 without stopping an operation of the LACU 200, as long as the number of operational power supply modules 230 exceeds a minimum threshold. As shown in FIG. 23, each power supply module 230 can include a handle 2304 which can facilitate easy removal and installation of the power supply module 230 within the power supply unit 226. As further shown, a controller module 2302 can be provided in the power supply unit 226 and can provide interfaces for wired connections into the power supply unit (e.g., Ethernet connections, USB connections, etc.). In some cases, the controller module 2302 can include a controller for controlling an operating mode for the power supply modules 230 or the power supply unit 226 as a whole, and can further provide interfaces to allow a user to set an operating mode of the power supply modules 230 or the power supply unit 226 as a whole.

In some cases, each of the power supply modules 230 of the power supply unit 226 can be connected to (e.g., can receive power from) each power inlet of a pair of redundant power inlets (e.g., inlets 350, shown in FIG. 10). For example, all of power supply modules 230a, 230b, 230c, 230d, 230e, 230f can be connected to both a first power inlet and a second power inlet (e.g., inlets 350, shown in FIG. 10). In some cases, the first power supply can be prioritized, so that each of the power supply modules 230 receive power from the first power inlet while the first power supply is available, and only receive power from the second power inlet when the first power inlet is unavailable. In some examples, individual power supply modules can prioritize different power inlets to be used as a primary power inlet for the power supply module. For example, power supply modules 230a-f can each be connected to a first power inlet and a second power inlet, and power supply modules 230a, 230b, 230c can prioritize power from the first power inlet, while power supply modules 230d, 230e, 230f can prioritize power supplied by the second power inlet. In this configuration, if either of the first power inlet or the second power inlet fails or is disconnected, all of the power supply modules 230 can receive power from the other (e.g., the operational) power inlet.

In some cases, three-phase power is received at the power inlets (e.g., power inlets 350 shown in FIG. 10), and the power supply modules 230 can filter a signal received from an inlet to process only a single phase of AC power from a given power inlet. For example, power supply module 230a can be connected to a first phase of AC power from a first power inlet, power supply module 230b can be connected to a second phase of AC power from the first power inlet, and power supply module 230c can be connected to a third phase of AC power from the first power inlet. In some cases, phases of AC power can be balanced across power supply modules of a power supply unit. In some cases, each power supply unit can convert an AC power received from an inlet into a DC power for powering components of a cooling unit (e.g., the LACU 200, shown in FIG. 2). Other configurations are possible, and power supply units can include more than 6 power supply modules or less than 6 power supply modules. Further, in some cases, LACU 200 can include more than one power supply unit.

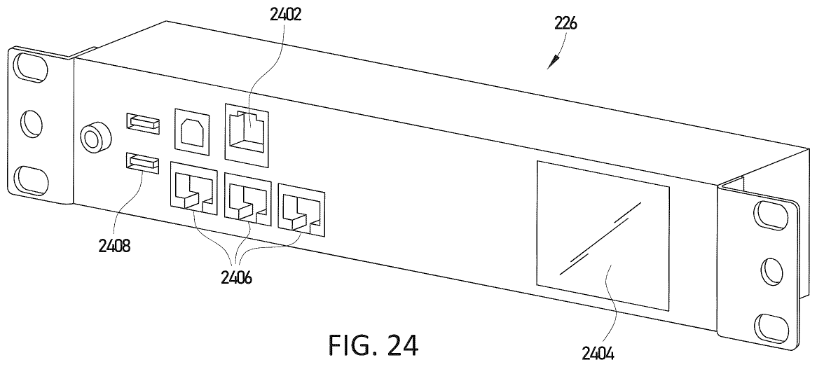

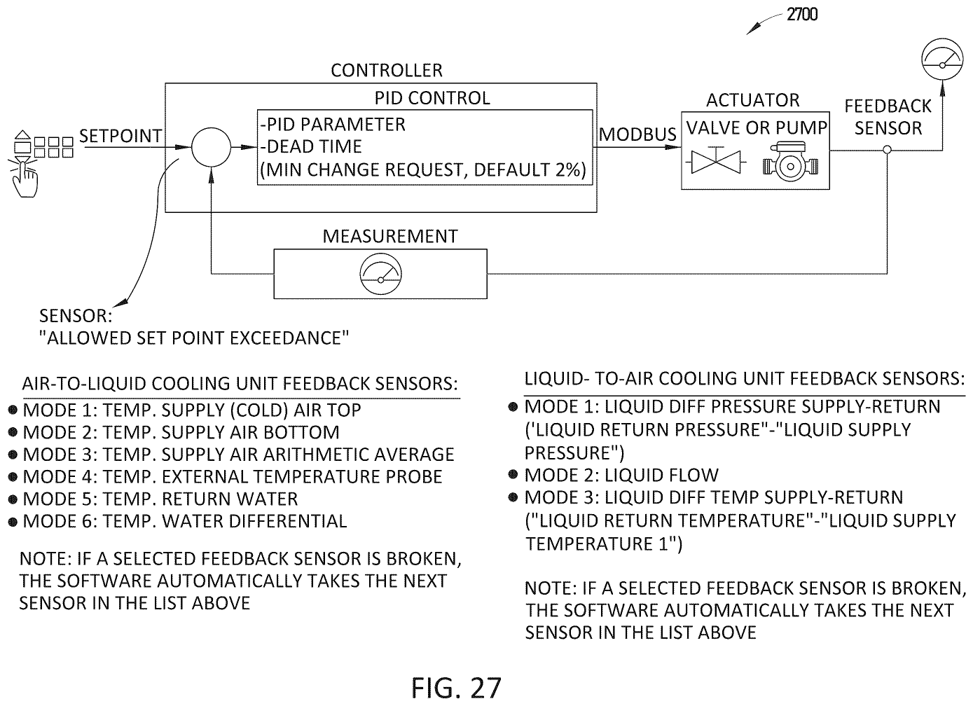

Referring to FIG. 24, an isometric view of an example interface board 2400 that can be used in the LACU 200 is shown, in accordance with some aspects of the disclosure. The interface board 2400 can include connections for sensors of the LACU 200 (e.g., sensors of the sensor list in FIGS. 27A and 27B). The interface board 2400 can have a network interface 2402 (e.g., a Gigabit Ethernet interface (GbE)) for connecting to other components within the data center, and a user can access the interface board 2400 through an LCD output 2404 provided on the unit, or through a web interface. In addition to the network interface 2402 described above, the interface board 2400 can include ports 2406 for receiving sensor data, including analog or digital data. The interface board 2400 can provide monitoring capabilities for monitoring sensor values against set values and can provide alerting when the sensor values fall outside of a safe operating region defined in the LACU 200.

As illustrated, the interface board 2400 provides three sensor management ports 2406, with each port 2406 being capable of monitoring up to 16 sensor devices. A total length of cable connected to each port can be 40 meters, for example. The interface board 2400 can support multiple industry standard protocols for communication and alerting, e.g., SNMP, SMTP, HTTPS, BACnet, Modbus/TCP, and HPI. The interface board 2400 can include USB ports 2408 and analog and digital input ports to directly read sensors, for example, sensors with an output of 10 volts. In addition to monitoring physical parameters like temperature, humidity, smoke, door status or water intrusion, a management gateway can also monitor in rack chillers and in row coolers with a plug and play installation. The setup and installation of the management gateway with security features, sensor configurations, user management functionality, and alarm and log management can be done through a built in web interface, for example. Access to the interface board 2400 can primarily be provided through the network interface 2402, though, supporting industry standard protocols such as noted above.

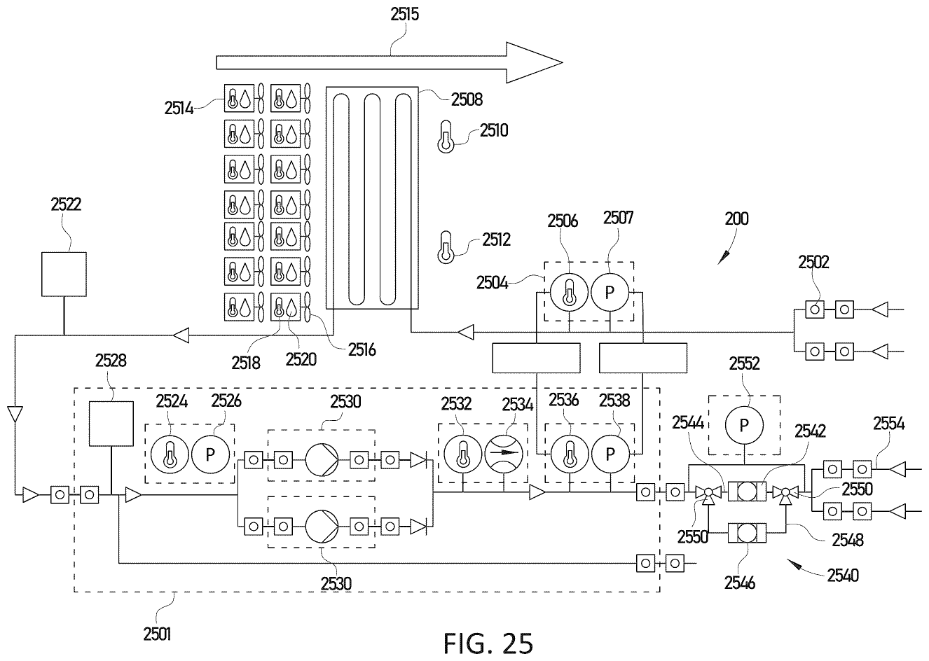

Referring to FIG. 25, an example schematic diagram representing different components and functionality of the LACU 200 is shown, in accordance with some aspects of the disclosure. The LACU 200 is shown to include an RPU 2501 (e.g., analogous to the RPU 204) to provide closed loop circulation when coupled to a server unit or other electrical components to be cooled. The LACU 200 also includes a liquid return line manifold 2502 (e.g., analogous to the inlet manifold 302) with a first sensor module 2504 including a temperature liquid return sensor 2506 and a pressure liquid return sensor 2507. The first sensor module 2504 can be positioned on the inlet manifold 2502 (e.g., the first sensor module can be included in sensor 1312 mounted to manifold 1300, shown in FIG. 13). The first sensor module 2504 can also be positioned at any other point in the LACU 200 fluidly upstream of a LAHX 2508 (e.g., analogous to the LAHX 202) which can include a top air temperature sensor 2510 to measure a temperature of an air along a top of the LAHX 2508, and a bottom air temperature sensor 2512 to measure a temperature of an air along a bottom of the LAHX 2508.

The LACU 200 is also shown to include a plurality of fan modules 2514 (e.g., analogous to the fans 206), which, in the illustrated example, includes 14 fan modules 2514, each including a single fan. Each of the fan modules 2514 can be placed adjacent to the LAHX 2508 and can include three sensors, including a fan speed sensor 2516, an air temperature sensor 2518, and an air humidity sensor 2520. The fan modules 2514 can produce an air flow 2515 across the LAHX 2508 to cool a liquid flowing through the LAHX 2508. Cooled liquid flowing out of the LAHX 2508 can pass toward the RPU 2501 past one or more external bladder expansion tanks 2522 that accommodate any thermal expansion of air, liquid, or fluids in the system. Properties of the liquid entering the RPU 2501 are sensed by a RPU suction temperature sensor 2524 and an RPU suction pressure sensor 2526. In some cases, as illustrated, the RPU 2501 can include an internal bladder expansion tank 2528 to accommodate any thermal expansion of air, liquid, or fluids in the RPU 2501.

The liquid of the system then passes through one or both of a pair of pump cassettes 2530 (e.g., analogous to the pump cassettes 210a, 210b) in the RPU 2501. The pump cassettes 2530 can each include a pump speed sensor. The liquid can exit the pump cassettes 2530 and flow past additional sensor modules, including a supply liquid temperature sensor 2532 and a liquid supply flow rate sensor 2534. A second sensor module 2535 can be positioned downstream of the pump cassettes 2530, and can include a liquid temperature sensor 2536 and a liquid pressure sensor 2538. In some cases, a differential temperature can be calculated between a supply temperature of a liquid measured at fluid temperature sensor 2506 and a return temperature of liquid measured at liquid temperature sensor 2536. Similarly, a differential pressure can be calculated between a supply pressure measured at pressure sensor 2507 and a return pressure measured at 2538.

While in the illustrated example, the second sensor module 2535 is positioned in the RPU 2501, in other examples, it can be advantageous to position the second sensor module 2535 at an outlet of a cabinet of the LACU 200 (e.g., along manifold 2554 shown in FIG. 25). In some examples, a control system for the RPU 2501 is located onboard the RPU 2501. In some cases, a control module of the RPU 2501 can provide control signals to fan modules 2514 to control a rotation of fans thereof. In some cases, each pump cassette 2530 can include a local controller for controlling aspects of a corresponding pump of the pump cassette. Using the various sensors described herein, the control system can control a speed of pumps and/or the fans to achieve target values for cooling the fluid in the system.

The liquid can flow from the RPU 2501 through a filter assembly 2540 which can filter the fluid along either or both of a primary filter 2542 of a primary flow path 2544, or a secondary filter 2546 of a secondary flow path 2548. Valves 2550 (e.g., three-way valves) can be provided at an entry and exit of the primary and secondary flow paths, to selectively allow fluid through either or both of the primary flow path 2544 and the secondary flow path 2548 (e.g., as described with respect to FIGS. 14 and 15). A differential pressure sensor 2552 can sense a differential pressure between a fluid upstream of the primary and secondary flow paths 2544, 2548, and a fluid downstream of the primary and secondary flow paths 2544, 2548. A differential pressure sensed by the differential pressure sensor 2552 that is above a differential pressure threshold can indicate a need for servicing one or more of the filters 2542, 2546. Fluid can flow from the filter assembly 2540 to a return manifold 2554 to cool electrical equipment downstream of the LACU 200.

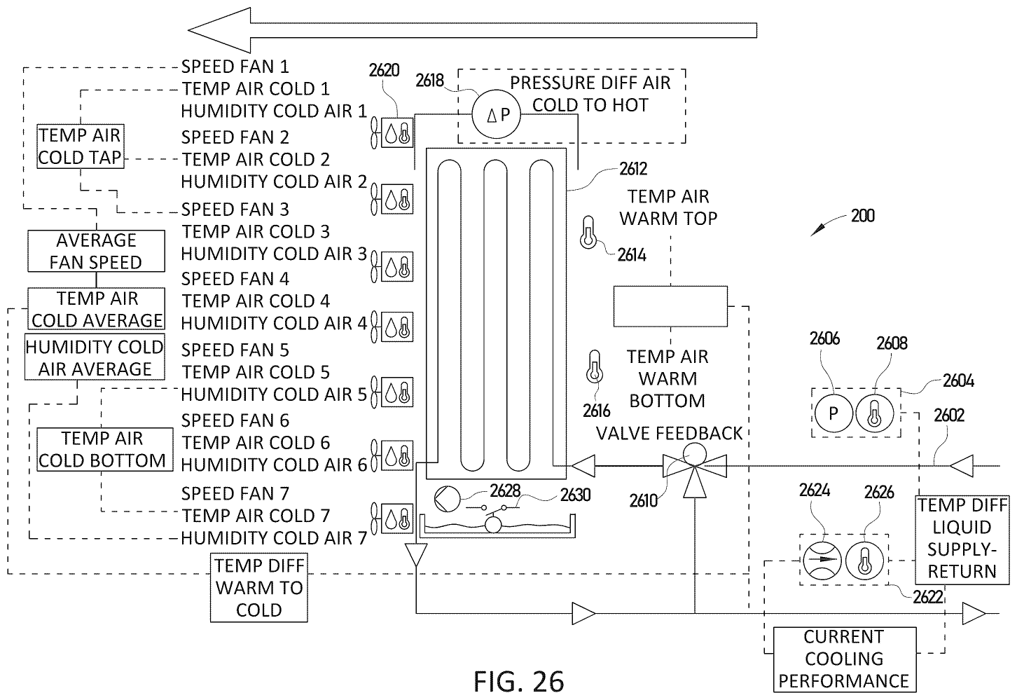

Referring to FIG. 26, another example schematic diagram representing different components and functionality of the LACU 200 is shown, in accordance with some aspects of the disclosure. In the implementation of the LACU 200 represented in FIG. 26, the LACU 200 is connected to a water supply, such as a pressurized water supply for a building. As shown, the system includes a liquid return line 2602 that passes a sensor module 2604 including a pressure liquid supply sensor 2606 and a temperature liquid supply sensor 2608. The liquid passes through a three-way motorized valve 2610 before entering a heat exchanger 2612 (e.g., analogous to the LAHX 202) with a temperature air warm top sensor 2614 and a temperature air warm bottom sensor 2616. The heat exchanger 2612 further includes a pressure differential air cold to hot sensor 2618. The heat exchanger 2612 can include seven fan modules 2620 (e.g., analogous to the fans 206). Each of the fan modules 2620 can be placed adjacent to the heat exchanger 2612 and can include a fan speed sensor, a temperature air cold sensor, and a humidity cold air sensor. The sensed parameters can be analyzed by a control system to calculate a number of parameters, such as temperature air cold top, average fan speed, temperature air cold average, humidity cold air average, temperature air cold bottom, and temperature differential warm to cold. The liquid exists the heat exchanger 2612 and flows past a final set of sensors 2622 including a liquid flow rate sensor 2624 and a temperature liquid return sensor 2626. Additional parameters can be calculated, including temperature differential supply-return and current cooling performance. The system can further include a condensate pump 2628, the state of which can be monitored by calculating the parameters noted above, the status of which can be controlled using a condensate level switch 2630.

In cases, control systems and processes can be implemented by controller of a cooling system (e.g., the cooling system 1) to achieve a desired cooling rate, maintain operating parameters of a cooling unit within threshold ranges, achieve a power efficiency, etc. For example, referring specifically to FIG. 25, a controller can provide signals to fans 2514 to increase a flow rate of air across the heat exchanger 2508 in order to achieve a target outlet temperature for fluid of the LACU 200. Additionally, or alternatively, a speed of one or more of the pumps 2530 can be adjusted to induce a target pressure or pressure difference in the system, or to achieve a target temperature or temperature differential for temperatures measured at different points along a liquid cooling circuit. In some cases, the fans 2514 and the pumps 2530 can be controlled independently to achieve different set points for operating parameters of the LACU 200. In some cases, the fans 2514 and the pumps 2530 can be controlled in coordination. In some cases, one of the pumps 2530 or the fans 2514 can be controlled to operate at a set value (e.g., fan speed or pump speed), which is not changed to achieve a target for an operating parameter of the LACU 200.

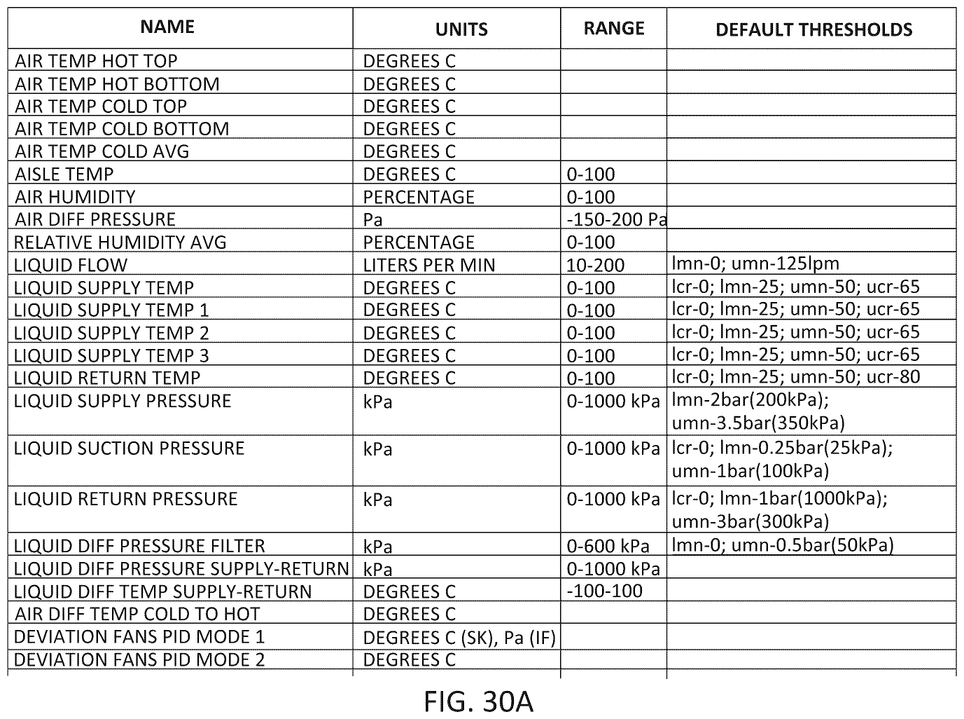

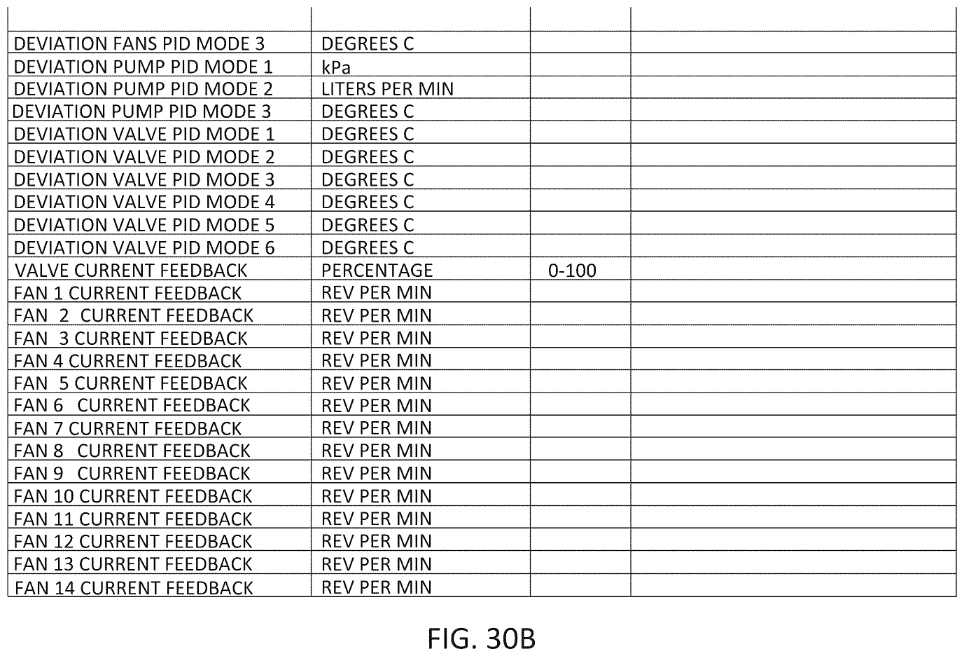

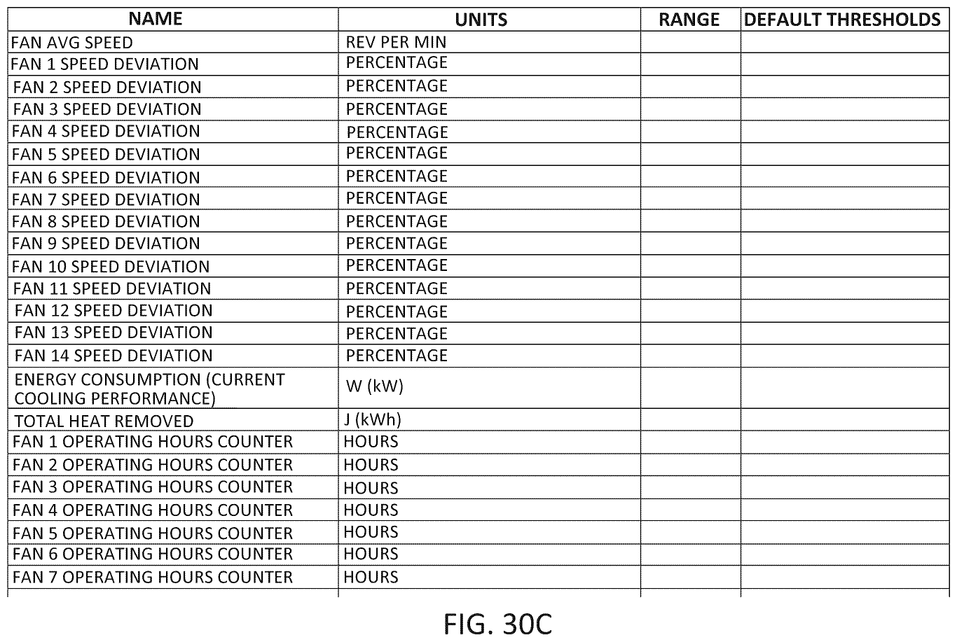

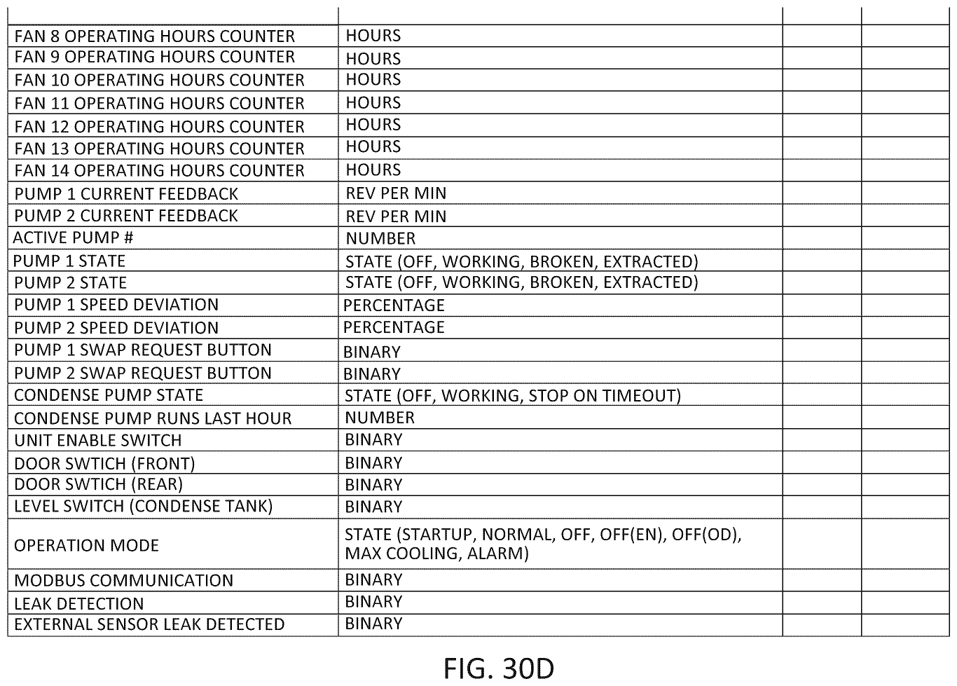

Actuators (e.g., fans 2514 and pumps 2530 shown in FIG. 25) can be controlled according to proportional integral derivative controls to achieve corresponding set points for operating parameters. For example, a controller (e.g., control modules 214a, 214b) can have programmed thereon operating ranges for operating parameters of the LACU 200 (e.g., as listed in FIGS. 30A-30D), set points for operating parameters, and gains of one or more proportional-integral-derivative (PID) controllers to be implemented by the controller. Operating parameters, set points, and gains can in some cases be preprogrammed at a memory of the controller, or can be set by a user at an input interface of the controller (e.g., a graphical user interface, a web interface, a command line interface, an ethernet interface, a Modbus interface, etc.). The controller can implement a PID control to vary an input into an actuator (e.g., a pump as shown, which can be one or more pumps housed in cassettes 210a, 210b shown in FIG. 2, or pumps 2530 shown in FIG. 25) to achieve a set point (e.g., a target value) for a measurement of a value from a feedback sensor. A measurement from a feedback sensor can be provided back to the controller, which can determine, based on the measurement, an error relative to the desired set point, and can output a signal to the actuator to adjust an operation thereof (e.g., a pump speed). This process can be continuously implemented and can iteratively measure a value, compare that measurement to a set value (e.g., calculate an error), and generate a signal to an actuator to produce a desired output for the feedback sensor.

Referring to FIG. 27, a block diagram of a first example feedback control system 2700 that can be used in the LACU 200 is shown, in accordance with some aspects of the disclosure. The control system 2700 can implement PID control to operate one or more pumps as actuators (e.g., pumps 2530 shown in FIG. 25, or pump housed in cassettes 210a, 210b shown in FIG. 2). In some examples, the pumps can be operated according to one of three operating modes, as shown, with each operating mode corresponding to a give sensor or set of sensors of the system. For example, in mode 1, as shown, the pumps can be operated to achieve a target value for a differential pressure between a supply and return of a liquid-to-air cooling unit (e.g., the inlet and the outlet of LACU 200). With reference to FIG. 25, for example, in mode one, a target value can be a difference between a pressure measured at pressure sensor 2507 (e.g., an inlet or return pressure) and a pressure measured at pressure sensor 2538 (e.g., an outlet or supply pressure). The controller can provide a signal (e.g., to variable frequency drives of one or more of the pumps) to increase a pump speed or decrease a pump speed to achieve the pressure differential. In some cases, mode 1 is a default mode of operation for a liquid-to-air cooling unit. In some cases, an operator (e.g., a user) can select a mode (e.g., including mode 1) in which to operate controls to control a pump speed of the system.

In some cases, the mode of a controller can at least partially depend on an operational state of one or more components of the LACU 200. For example, if a feedback sensor for a given PID control or mode of a PID control is not operational, or is not communicative with a controller, the controller can switch to another mode, to implement a PID control to achieve a set point for a different operating parameter of the cooling unit. For example, if one or both of sensors 2507, 2538 are not operational, the controller may not be able to implement mode 1 as illustrated, and the controller may automatically switch to another mode of operation for implementing a PID control (e.g., mode 2 or 3). For example, the controller can switch to Mode 2 to control a speed of pumps 2530 to achieve a set value for liquid flow through the LACU 200, as can be measured, for example, by flow rate sensor 2534.

When neither of modes 1 or 2 are feasible, as when either or all of sensors 2507, 2538, 2534 are operational, the controller can implement a PID control according to mode 3, to achieve a differential temperature between an inlet and outlet (e.g., a return and supply) of the LACU 200, as can be measured as a difference between temperatures received at temperature sensor 2506 and temperature sensor 2536 respectively. In some cases, either of modes 2 or 3 can be the primary or default mode, and a controller can switch to the other respective modes upon an unavailability (e.g., a failure or lack of communication with feedback sensors of the primary mode). In some cases, additional modes can be implemented to achieve set points for any measured value or differentials between measured values.

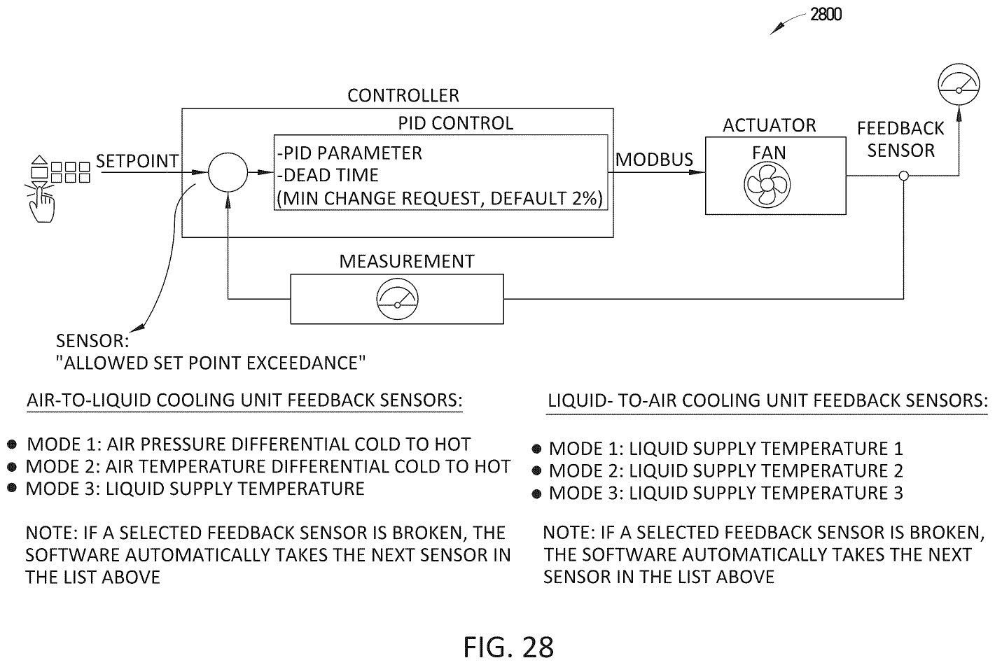

Referring to FIG. 28, a block diagram of a second example feedback control system 2800 that can be used in the LACU 200 is shown, in accordance with some aspects of the disclosure. In the control system 2800, a controller for the LACU 200 controls a speed of one or more fans (e.g., the fans 206) of the LACU 200 to achieve a set point for a value of a feedback sensor. The feedback control system 2800 can be implemented in addition to or alternatively to the feedback control system 2700. As shown, the fans can be controlled in any of modes 1-3 to achieve an output temperature for liquid of the liquid coolant circuit. For example, mode I can rely on temperature sensor 2536 as a feedback sensor, mode 2 can rely on temperature sensor 2532 as a feedback sensor, and mode 3 can rely on temperature sensor 2524 as a feedback sensor. The modes provided for either or both of the feedback control systems 2700 and 2800 are provided for illustration and are not intended to be limiting.

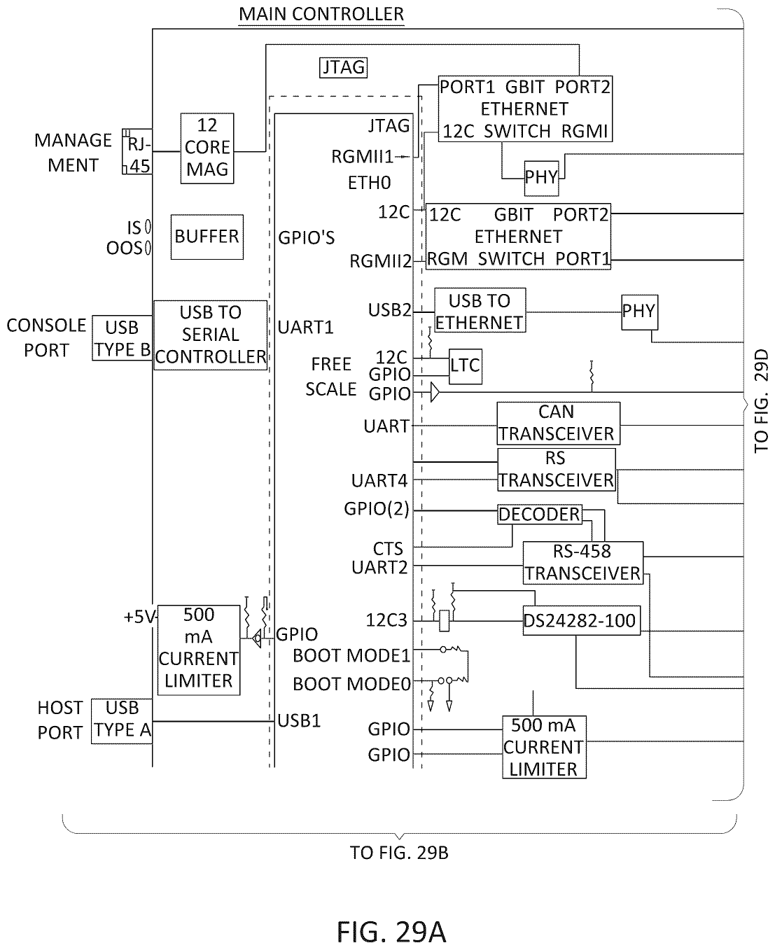

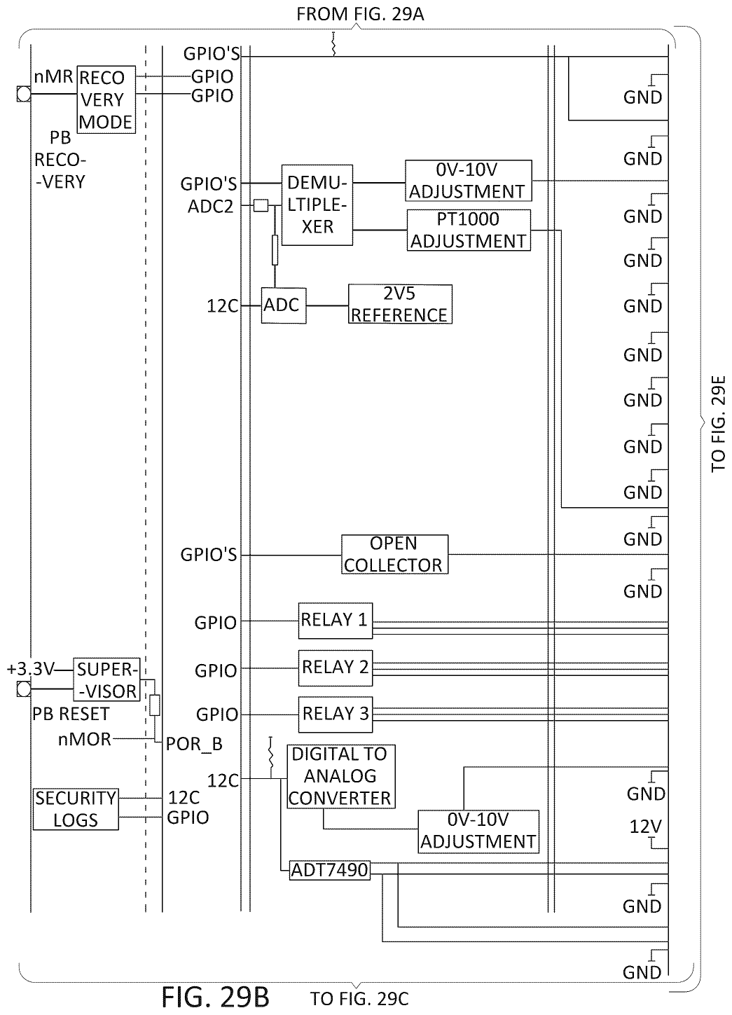

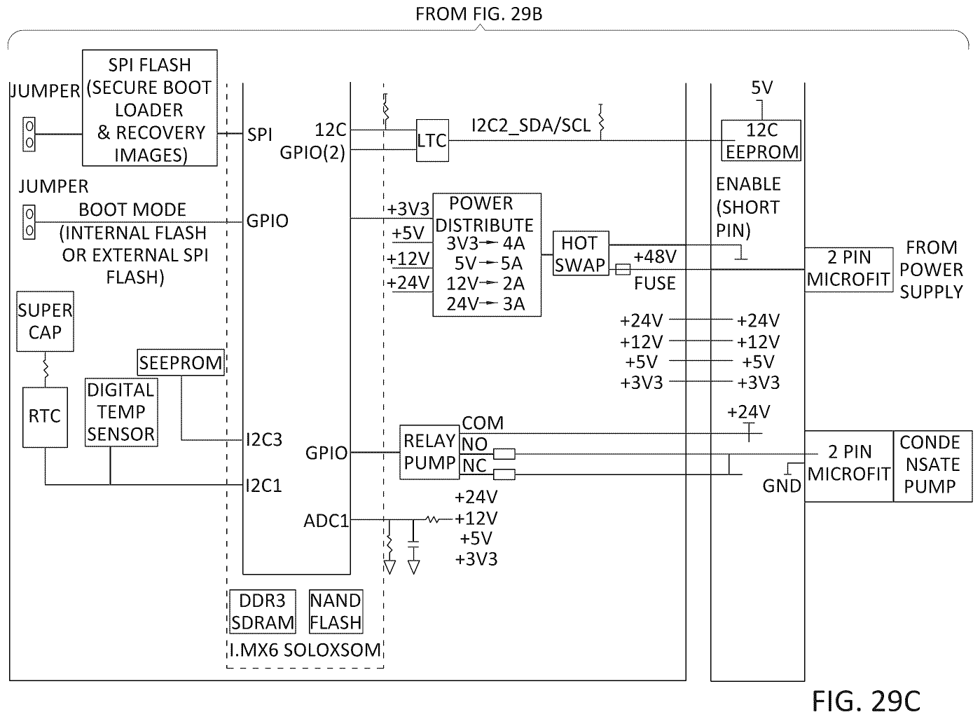

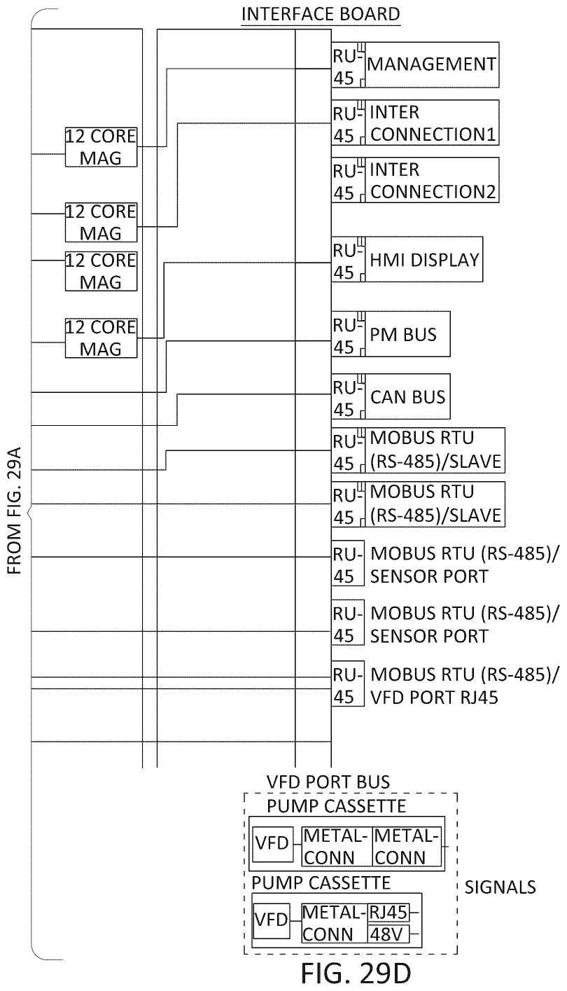

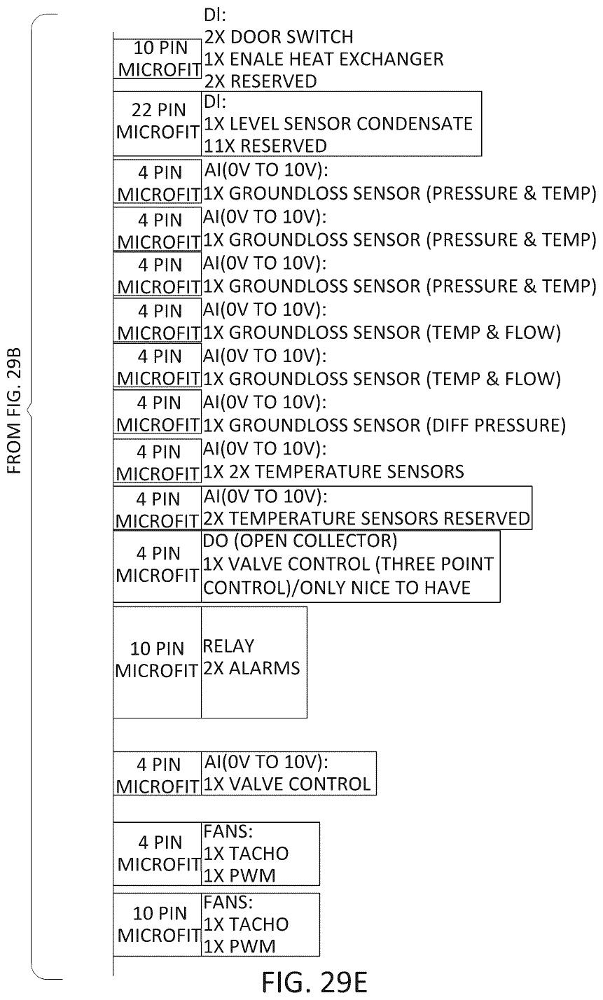

Referring to FIGS. 29A-29E, a schematic diagram showing an example controller and an example interface board that can be used in the LACU 200 is shown, in accordance with some aspects of the disclosure. The electrical schematic shown in FIGS. 29A-29E is provided as an example implementation to help the skilled person understand the subject matter of the present disclosure and is not intended to be limiting.

Referring to FIGS. 30A-30D, two tables showing examples of sensors that can be used in the LACU 200 is shown, in accordance with some aspects of the disclosure. Subsets of these sensors can used to monitor and control the LACU 200 and/or the LAHX 202, for example. The sensors can be connected to a control system and supported for communication with the control system firmware. Another subset of the sensors can be used by the feedback control system, including those sensors shown in FIGS. 25 and 26, for use in the feedback control systems 2700 and 2800. Some of the sensors can be only informational, for example, to determine whether certain temperatures are too high or certain fan or pump speeds are too low. In some examples, active operation only relies on two sensors for the pump control loop and the fan control loop. Some of the sensors may be redundant so that if sensors malfunction, the system uses fallback sensors to continue operation. The sensors shown in FIGS. 30A through 30D are provided as examples to help the skilled person understand the subject matter of the present disclosure and is not intended to be limiting.

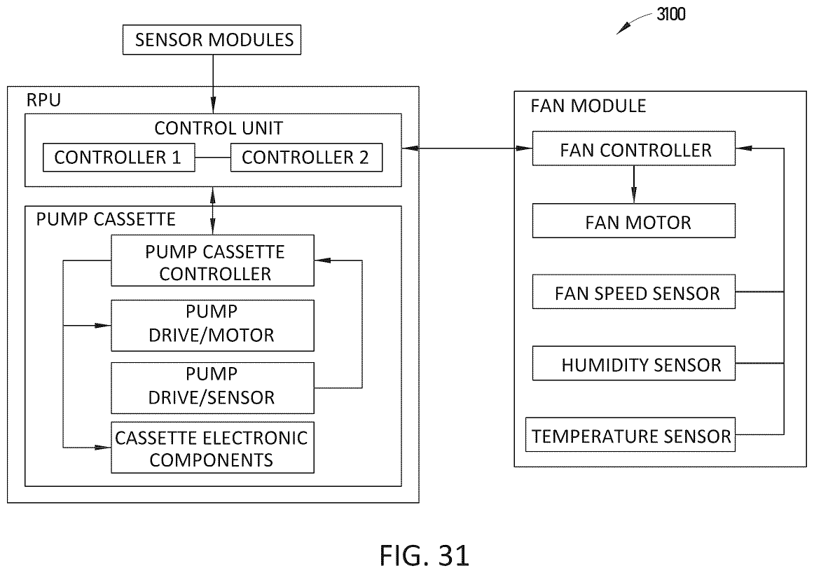

Referring to FIG. 31, a block diagram showing an example control system 3100 that can be used in the LACU 200 is shown, in accordance with some aspects of the disclosure. As shown, the control system 3100 can include an RPU (e.g., the RPU 204), a fan module (e.g., the fans 206), and a sensing module. The sensing module of the control system 3100 can include temperature sensors, pressure sensors, flow sensors, humidity sensors, or other know sensor types, such as any or all of sensors 2506, 2507, 2510, 2512, 2518, 2520, 2516, 2524, 2526, 2532, 2534, 2536, 2538, and 2552 shown in FIG. 25, or any of the sensors listed in the tables of FIGS. 30A through 30D. The RPU shown can include one or more pump cassettes and a control unit. The control unit can include two controllers: controller 1 and controller 2 (e.g., controller 1 can be housed in the control module 214a and controller 2 can be housed in control module 214b). In some examples, controllers 1 and 2 can be operated in an active-passive mode, with only one of the controllers being active at a particular time. For example, controller 1 can be a primary controller and controller 2 can be a secondary or backup controller.

The fan module is shown to include a fan controller that can provide local controls for the fan module. The fan module is further shown to include a fan speed sensor, a humidity sensor, and a temperature sensor. Each of the fan speed sensor, the humidity sensor, and the temperature sensor can provide measurements for a sensed value to the fan controller. The fan module can further include a fan motor, as shown, which can receive a signal from the fan controller to drive an operation of the fan motor. As further shown, the fan controller can be in communication with the control unit. In normal operation of the control system 3100, the fan controller can provide sensed values from any of the described sensors to the control unit (e.g., to either or both of controller 1 and controller 2) and can receive a signal from the control unit to drive operation of the fan motor. In other cases, including when a communication between the fan module and the control unit is interrupted, the fan controller can autonomously control a speed of the fan motor, according to instructions preprogrammed in the fan controller. In some examples, when a fan controller is autonomously driving a fan motor, it can operate a feedback control system based on sensor parameters obtained from sensors of the fan module.

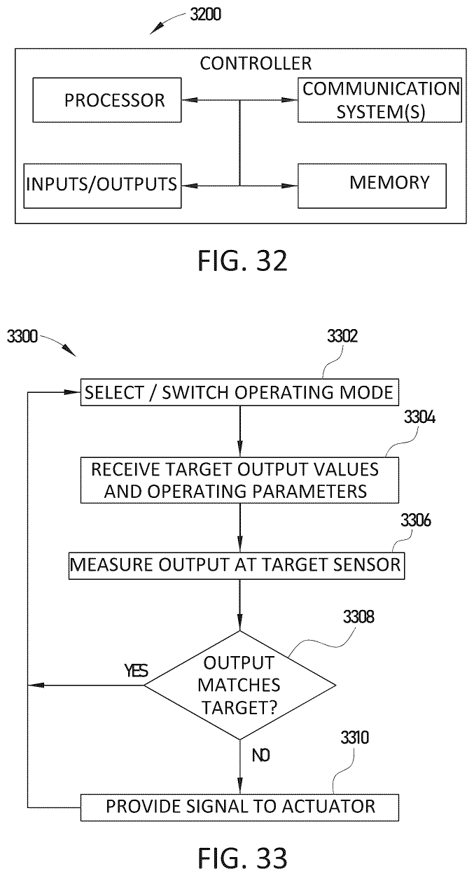

As further shown in FIG. 31, the pump cassette can include a pump cassette controller, which can provide control signal for one or more of a pump drive/motor and cassette electronic components (e.g., light-emitting diodes (LEDs), fans, locking systems, servo motors, linear actuators, speakers, etc.). The pump cassette controller can receive measured signals of a pump speed from a pump drive/sensor, as shown. In some examples, a pump cassette can include additional sensing components to sense operational parameters of the pump cassette. The pump cassette controller can be in communication with the control unit (e.g., via a wired or wireless connection), and can receive instructions from one or both of controller 1 and controller 2 to drive a speed the pump drive/motor and/or control the cassette electronic components. In the event that communication is lost between the control unit and the pump cassette controller, the pump cassette controller can control elements of the pump cassette autonomously until a connection is restored with the control unit. In some examples, each of the controller 1, controller 2, the pump cassette controller, and the fan controller can be an instance of the controller 3200 shown in FIG. 32, which is described below.

The control unit can be in communication with the sensor modules to receive sensed values from sensors thereof. The control unit can provide signals (e.g., instructions) to one or more of the fan controller and the pump cassette controller to implement a feedback control system (e.g., 2700 and 2800) to achieve a set value for a sensor of the sensor modules. The control unit can be in direct communication with the sensors of the fan module and the pump cassette. The communication between the components of the control system 3100 can be carried out over wired connections (e.g., a Modbus, an ethernet connection, USB connections, etc.) and/or over wireless connections (e.g., a Wi-Fi, cellular, Bluetooth, etc.).

Referring to FIG. 32, a block diagram showing an example controller 3200 that can be used in the LACU 200 is shown, in accordance with some aspects of the disclosure. The controller 3200 in some examples can be implemented as a programmable logic controller (PLC). The controller 3200 provides an example implementation of one or more hardware aspects of the control unit 212, for example. The controller 3200 can include a processor, one or more input/output (I/O) interfaces, communication system(s), and memory. The processor can be implemented using any suitable hardware processor or combination of processors, such as a central processing unit (CPU), a graphics processing unit (GPU), an application specific integrated circuit (ASIC), a field-programmable gate array (FPGA), etc. The I/O interfaces can include any suitable display device, such as a computer monitor, a touchscreen, a television, any suitable input devices and/or sensors that can be used to receive user input, such as a keyboard, a mouse, a touchscreen, a microphone, a camera, etc. Inputs can be received at an interactive display (e.g., human machine interface (HMI)) which can present a user interface through which an operator can view system parameters, and set control parameters (e.g., set an operating mode, define set points for temperature or pressure, set a language of the system, etc.).

The communication systems of the controller 3200 can include any suitable hardware, firmware, and/or software for communicating information over any suitable communication networks. For example, the communication systems can include one or more transceivers, one or more receivers, one or more communication chips and/or chip sets, etc. The communications systems can include hardware, firmware and/or software that can be used to establish a Wi-Fi connection, a Bluetooth connection, a cellular connection, an Ethernet connection, etc. In some examples, inputs can be received at the controller 3200 through the communication systems (e.g., over a communication network), such as through an application programming interface, command line interface, or a web interface can be provided for the LACU 200 to allow an operator to control the LACU 200 remotely.

The memory can include any suitable storage device or devices that can be used to store instructions, values, etc., that can be used, for example, by the processor of the controller 3200 to implement control loops and algorithms, to store logs of the controller 3200, etc. The memory can include any suitable volatile memory, non-volatile memory, storage, or any suitable combination thereof. For example, the memory can include random access memory (RAM), read-only memory (ROM), electronically erasable programmable read-only memory (EEPROM), one or more flash drives, one or more hard disks, one or more solid state drives, one or more optical drives, etc. The memory can have encoded thereon one or more programs for controlling the operation of the controller 3200.

Referring to FIG. 33, a flowchart illustrating an example process 3300 for controlling operation of the LACU 200 is shown, in accordance with some aspects of the disclosure. The process 3300 can be performed by the control unit 212, for example. At block 3302, the process 3300 can select or switch an operating mode of the LACU 200. The operating mode can include system parameters for operation of components of the LACU 200 (e.g., maximum and/or minimum speeds of pumps and/or motors, a primary and secondary controller, a set point for a temperature, differential temperature, flow rate, pressure, differential pressure, etc.). As another example, the operating mode can include a mode of a feedback loop control procedure, such as described with respect to FIGS. 27 and 28 (e.g., modes for operation of respective PID controls). Further, in some cases, the operating mode can include a mode of one or more pumps of the RPU 204. For example, pumps can be operated in a parallel mode, with each pump operating to induce a flow through the RPU 204. Alternatively, pumps of the RPU 204 can operate in an active/passive configuration, with one pump being a primary pump and another pump being activated only when the primary pump is not operational.

The operating mode can further include which controller of a pair of controllers (e.g., controller 1 and controller 2 shown in FIG. 31) to use to implement a control system for the LACU 200. In some examples, a user input can be provided to select or switch an operating mode. In some cases, system parameters can dictate an operating mode, as, for example, when failure of a feedback sensor of an active PID control system necessitates a switch to a PID control for another feedback sensor, as described with respect to FIGS. 27 and 28. At block 3304, the process 3300 can receive target output values and operating parameters. In some examples, this can include performing a lookup on a database, or otherwise retrieving the values and parameters from a memory that is operatively connected to a processor implementing the process 3300. In some cases, an operator can be prompted for input to set one or more target output values and operating parameters. In some cases, operating values and target parameters can be values for operational parameters listed in the tables shown in FIGS. 30A through 30D.

At block 3306, a system implementing the process 3300 can measure an output at a target sensor. The target sensor can be a feedback sensor for a PID control implementation, as illustrated in FIGS. 27 and 28. In some cases the target sensor can be a sensor for which an operating range has been set (e.g., the target can be a sensor for a temperature for which the system include a maximum and/or minimum value for the output of the sensor). In some cases, the output from the target sensor is informational, and can be provided to a user at a display or other interface of the LACU 200. At block 3308, the process 3300 can check if the output matches a target. In some cases, the target is a target range for the output value (e.g., as set at block 3304). In some cases, the target is a set point of a PID controller for the output of the target sensor. If the output matches the target value (e.g., a sensed temperature is within a target range, a temperature at an outlet of the LACU 200 equals a set point for the temperature), the process 3300 can return to block 3302 to monitor for any updates to the system that can require switching the operating mode.

If, at block 3308, the output does not match the target, as when a measured value from a sensor falls outside of a specified range, or does not equal a set value, at block 3310, the process 3300 can provide a signal to an actuator. The signal can include instructions to increase or decrease a pump speed, as described with respect to FIG. 27, or to increase or decrease a speed of one or more fans, as described with respect to FIG. 28. In some examples, the signal can include instructions to shut down or halt a respective actuator, as when the output indicates a measured value falling outside of a safe operating range. In other examples, an actuator can include a valve to selectively allow or deny fluid flow through portions of the LACU 200. In some cases, the signal can be calculated based on an output of a PID control, as described with respect to FIGS. 27 and 28. Upon providing the signal to the actuator, the process 3300 can return to block 3302 to continue monitoring conditions of the LACU 200.

As noted, the LACU 200 can include hot-swappable components such as the pump cassettes 210a, 210b, the control modules 214a, 214b, the fans 206, and the power source modules 230a, 230b, 230c, 230d, 230e. Due to the design of LACU 200 including these hot-swappable components, some undesirable electrical characteristics may be exhibited by the LACU 200 in certain applications. For example, consider an implementation where both the pump cassettes 210a, 210b share a common power source (e.g., a 48V DC power supply). If the pump cassettes 210a, 210b are not electrically isolated from the power source (e.g., from a common system bus connected to the power source), the inrush current drawn by the pump cassettes 210a, 210b from the power source can be higher than desired. As a result, components including various types of electrical connector pins (e.g., blind mate connectors) can be damaged, and the control modules 214a, 214b can be forced to reboot upon connecting the pump cassettes 210a, 210b to the power source. Further, since the control modules 214a, 214b may share their internal capacitance if the pump cassettes 210a, 210b are not electrically isolated from the power source, significant voltage drops can be seen across the system bus upon connecting the pump cassettes 210a, 210b to the power source.

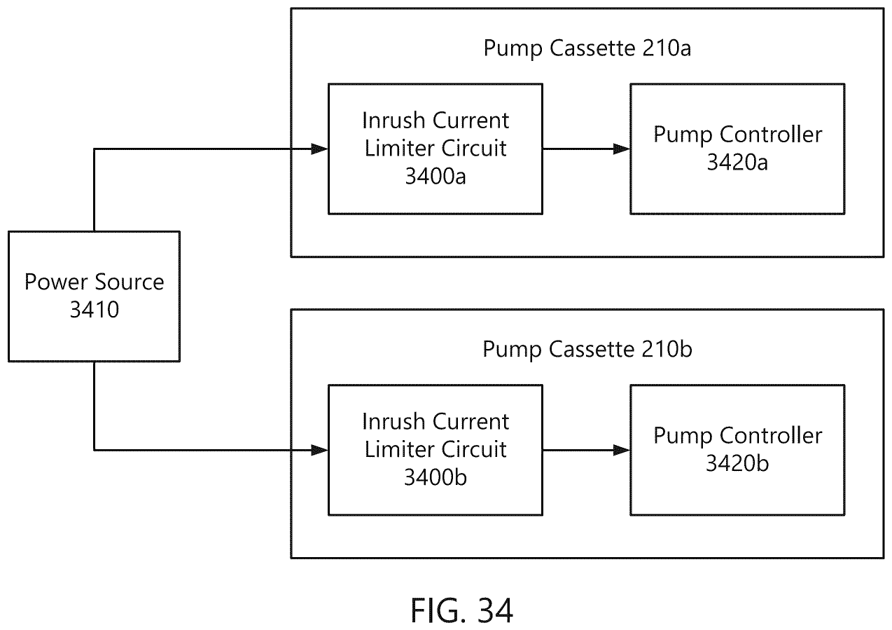

Referring to FIG. 34, a block diagram showing example inrush current limiter (ICL) circuits 3400a, 3400b that can be implemented in the pump cassettes 210a, 210b is shown, in accordance with some aspects of the disclosure. The inrush current limiter circuits 3400a, 3400b can be used to electrically isolate the pump cassettes 210a, 210b from a power source 3410 to prevent the undesirable electrical effects that may occur within the LACU 200 as detailed above. The power source 3410 can be implemented in a variety of ways, such as by using the power supply unit 226 and/or one or more of the power supply modules 230 as detailed above. Also shown in FIG. 34, the pump cassettes 210a, 210b can include pump controllers 3420a, 3420b, respectively. The pump controllers 3420a, 3420b can be the same as or similar to the control modules 214a, 214b as detailed above. The pump controllers 3420a, 3420b can be implemented as variable frequency drives (VFDs), in some examples.

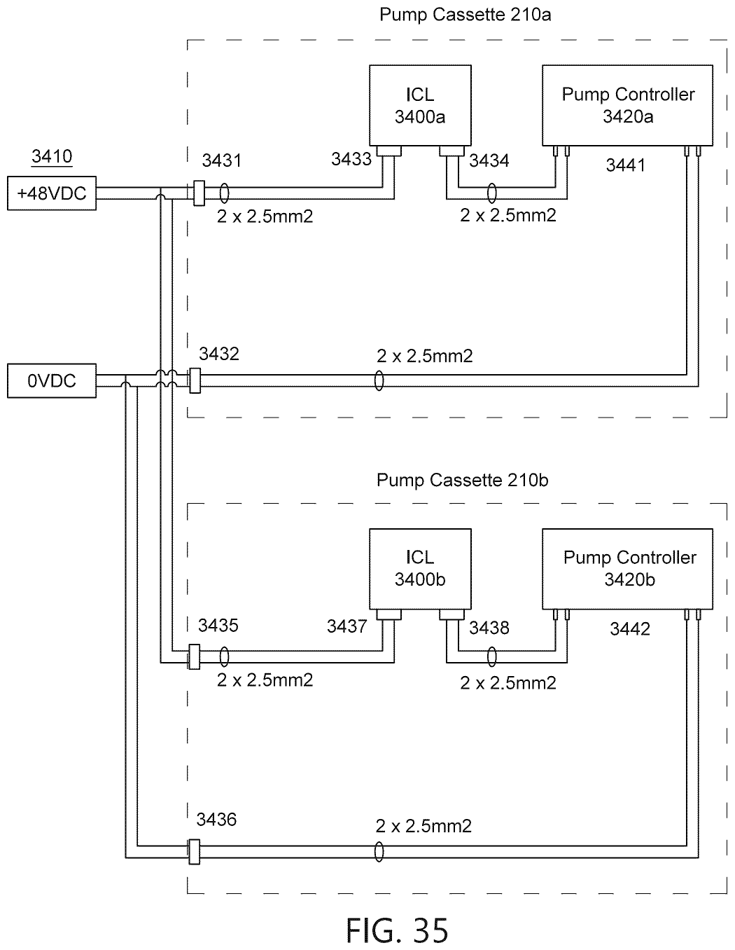

As shown in FIG. 34, the inrush current limiter circuit 3400a can be connected in series between the power source 3410 and the pump controller 3420a. Likewise, the inrush current limiter circuit 3400b can be connected in series between the power source 3410 and the pump controller 3420b. As a result of this design, the inrush current limiter circuits 3400a, 3400b can be used to electrically isolate the pump cassettes 210a, 210b from the power source 3410 to prevent undesirable electrical effects that may occur within the LACU 200 due to excessive inrush current. The inrush current limiter circuits 3400a, 3400b can be connected in series between the power source 3410 and the pump controllers 3420a, 3420b in a variety of manners, such as detailed below with respect to FIG. 35. This specific design also helps enable the pump cassettes 210a, 210b to be hot-swappable such that they are each removable from the LACU 200 without causing the LACU 200 to shut down. As noted, the pump cassettes 210a, 210b can be configured to operate in parallel to circulate fluid through the LACU 200 and provide cooling functionality. By using the inrush current limiter circuits 3400a, 3400b connected in series between the power source 3410 and the pump controllers 3420a, 3420b, capacitors of the pump cassettes 210a, 210b can be charged independently, thereby facilitating the hot-swap functionality.

Referring to FIG. 35, a block diagram showing an example implementation of the inrush current limiter circuits 3400a, 3400b within the LACU 200 is shown, in accordance with some aspects of the disclosure. In the implementation shown in FIG. 35, the power source 3410 is a single 48V DC power source that is connected to both of the pump cassettes 210a, 210b. That is, the pump cassettes 210a, 210b share a common power supply. Also shown in FIG. 35, various electrical connections are formed between the power source 3410, the inrush current limiter circuits 3400a, 3400b, and the pump controllers 3420a, 3420b. These electrical connections can be formed using specific types of electrical connectors and wiring to provide advantageous electrical characteristics within the LACU 200, as detailed further below. The wiring can have a cross-sectional area of 2.5 mm² in some examples to provide advantageous electrical characteristics within the LACU 200.

As shown in FIG. 35, many of the electrical connections between the power source 3410, the inrush current limiter circuits 3400a, 3400b, and the pump controllers 3420a, 3420b can be formed using two-pin electrical connectors. Specifically, a two-pin electrical connector 3431 can be used to connect the pump cassette 210a to the power source 3410 (+48 VDC), and a two-pin electrical connector 3432 can be used to connect the pump cassette 210a to ground. Further, a two-pin electrical connector 3433 can be used to connect the two-pin electrical connector 3431 to the inrush current limiter circuit 3400a, and a two-pin electrical connector 3434 can be used to connect the inrush current limiter circuit 3400a to the pump controller 3420a.

Likewise, a two-pin electrical connector 3435 can be used to connect the pump cassette 210b to the power source 3410 (+48 VDC), and a two-pin electrical connector 3436 can be used to connect the pump cassette 210b to ground. Further, a two-pin electrical connector 3437 can be used to connect the two-pin electrical connector 3435 to the inrush current limiter circuit 3400b, and a two-pin electrical connector 3438 can be used to connect the inrush current limiter circuit 3400b to the pump controller 3420b. In some examples, the two-pin electrical connectors 3431, 3432, 3433, 3434, 3435, 3436, 3437, 3438 can be implemented as two-pin Molex Mega-Fit electrical connectors, however other types of two-pin electrical connectors can also be used.

Also shown in FIG. 35, some of the electrical connections can be formed using clamped ferrules and/or ring connector lugs. As shown, a plurality of connectors 3441 are used to connect the inrush current limiter circuit 3400a to the pump controller 3420a via the two-pin electrical connector 3434. The connectors 3441 are also used to connect the pump controller 3420a to ground via the two-pin electrical connector 3432. Similarly, as shown, a plurality of connectors 3442 are used to connect the inrush current limiter circuit 3400b to the pump controller 3420b via the two-pin electrical connector 3438. The connectors 3442 are also used to connect the pump controller 3420b to ground via the two-pin electrical connector 3436. The connectors 3441, 3442 can each include four separate connectors used to connect the pump controllers 3420a, 3420b to the two-pin electrical connectors 3432, 3434, 3436, 3438, respectively, as shown. The connectors 3441, 3442 can include any combination and/or configuration of clamped ferrules and/or ring connector lugs, including AZ3 clamped ferrules, AZ3+ ring connector lugs, and/or other suitable types of clamped ferrules and/or ring connector lugs.

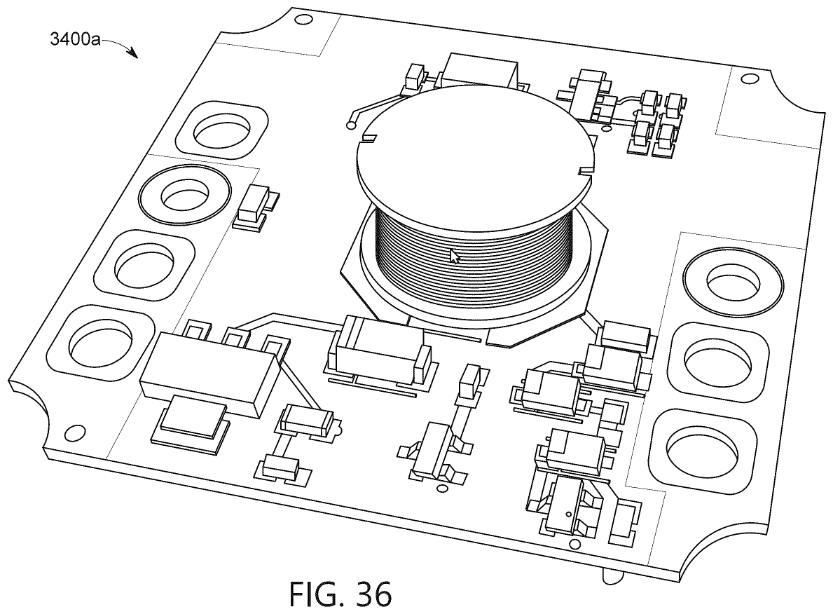

Referring to FIG. 36, a perspective illustration showing an example implementation of the inrush current limiter circuit 3400a is shown, in accordance with some aspects of the disclosure. As shown, the inrush current limiter circuit 3400a can be implemented on a single printed circuit board (PCB) assembly. As noted, the inrush current limiter circuit 3400a can be connected in series between the power source 3410 and the pump controller 3420a to electrically isolate the pump controller 3420a from the power source 3410 by limiting current flow from the power source 3410 to the pump controller 3420a, especially upon connecting the pump cassette 210a to the power source 3410. While the illustration of the inrush current limiter circuit 3400a shown in FIG. 36 includes through-holes that can be used for establishing lug connections and/or mounting of the inrush current limiter circuit 3400a, among other possible uses, the inrush current limiter circuit 3400a can also be designed to include on-board solder-style connection interfaces. By using these types of solder connections, manufacturing time for both the inrush current limiter circuit 3400a itself as well as the LACU 200 more broadly can be significantly reduced. Moreover, by providing the inrush current limiter circuit 3400a as a connectorized module that can be connected in in series between the power source 3410 and the pump controller 3420a, and can also be removable from the LACU 200, additional advantages in terms of manufacturability of the LACU 200 can also be provided. The inrush current limiter circuit 3400b can be implemented using a similar PCB assembly as shown in FIG. 36. As such, the inrush current limiter circuit 3400a can consist essentially of a first PCB assembly and the inrush current limiter circuit 3400b can consist essentially of a second PCB assembly.

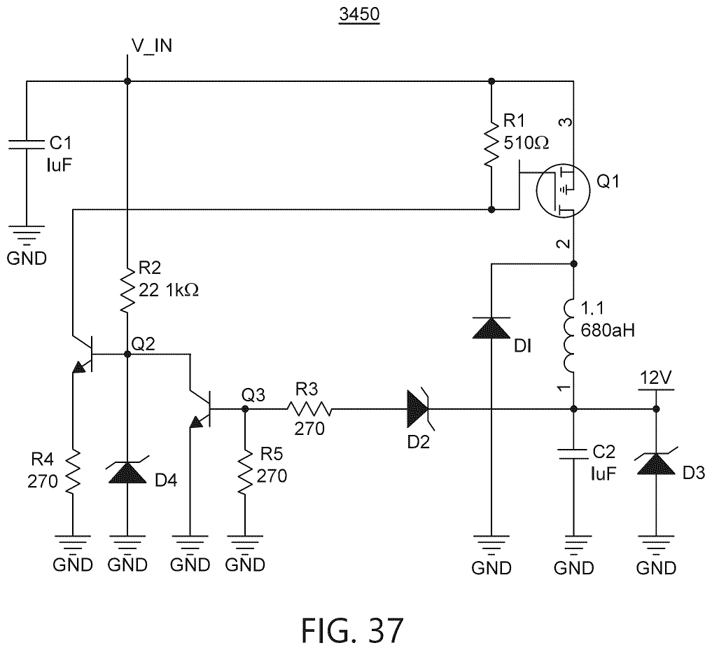

Referring to FIG. 37, an example switched-mode power supply circuit 3450 that can be used in the inrush current limiter circuit 3400a is shown, in accordance with some aspects of the disclosure. As shown, the switched-mode power supply circuit 3450 includes various electrical components such as diodes, resistors, a capacitor, an inductor, and transistors. The switched-mode power supply circuit 3450 can be connected to the power source 3410 and can be configured to convert electrical power from the power source 3410 efficiently using a switching regulator. The switched-mode power supply circuit 3450 can continually switch between different states including low-dissipation, full-on, and full-off states, for example, to provide a positive supply voltage (e.g., 12V). The switched-mode power supply circuit 3450 provides just one example of a power supply circuit that can be implemented in the inrush current limiter circuit 3400a, and other variations are possible and contemplated. The inrush current limiter circuit 3400b can include a similar circuit as the switched-mode power supply circuit 3450 shown in FIG. 37.

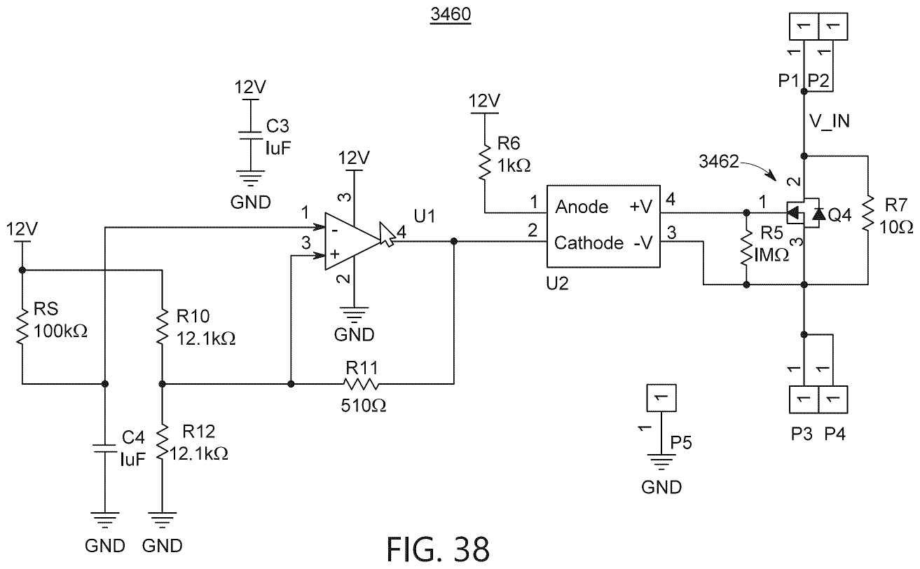

Referring to FIG. 38, an example switching circuit 3460 that can be used in the inrush current limiter circuit 3400a is shown, in accordance with some aspects of the disclosure. As shown, the switching circuit 3460 can operate using a positive input voltage (e.g., a positive supply voltage provided by the power supply circuit 3450) and can include an N-channel metal-oxide-semiconductor field-effect transistor (MOSFET) 3462. The N-channel MOSFET 3462 can be used to limit the inrush current drawn by the pump controller 3420a via the power source 3410 via a positive channel (leg) of the N-channel MOSFET 3462. The switching circuit 3460 can also include additional electrical components such as resistors, capacitors, and amplifiers as shown. The switching circuit 3460 provides just one example of a switching circuit that can be used in the inrush current limiter circuit 3400a, and other variations are possible and contemplated. For example, a switching circuit that limits current on a negative channel of a MOSFET could also be used to provide similar functionality. The inrush current limiter circuit 3400b can include a similar circuit as the switching circuit 3460 shown in FIG. 38.

It should be understood that the invention is not limited in its application to the details of construction and the arrangement of components set forth in the above description or illustrated in the drawings. The disclosure is capable of being implemented in various aspects and of being practiced or of being carried out in various ways. Also, it is to be understood that the phraseology and terminology used herein is for the purpose of description and should not be regarded as limiting. The use of terms such as “including”, “comprising”, “having”, and variations thereof is meant to encompass the items listed thereafter and equivalents thereof as well as additional items. Unless specified or limited otherwise, terms such as “mounted”, “connected”, “supported”, “coupled”, and variations thereof are used broadly and encompass both direct and indirect mountings, connections, supports, and couplings. Further, terms such as “connected” and “coupled” are not restricted to physical or mechanical connections or couplings.

Also, unless otherwise limited or defined, the term “or” indicates a non-exclusive list of components or operations that can be present in any variety of combinations, rather than an exclusive list of components that can be present only as alternatives to each other. For example, a list of “A, B, or C” indicates options of: A; B; C; A and B; A and C; B and C; and A, B, and C. Correspondingly, the term “or” as used herein is intended to indicate exclusive alternatives only when preceded by terms of exclusivity, such as “either”, “one of”, “only one of”, or “exactly one of”. For example, a list of “one of A, B, or C” indicates options of: A, but not B and C; B, but not A and C; and C, but not A and B. A list preceded by “one or more” (and variations thereon) and including “or” to separate listed elements indicates options of one or more of any or all of the listed elements.

For example, the phrases “one or more of A, B, or C” and “at least one of A, B, or C” indicate options of: one or more A; one or more B; one or more C; one or more A and one or more B; one or more B and one or more C; one or more A and one or more C; and one or more of A, one or more of B, and one or more of C. Similarly, a list preceded by “a plurality of” (and variations thereon) and including “or” to separate listed elements indicates options of multiple instances of any or all of the listed elements. For example, the phrases “a plurality of A, B, or C” and “two or more of A, B, or C” indicate options of: A and B; B and C; A and C; and A, B, and C.

In some implementations, different devices or systems disclosed herein can be utilized, manufactured, installed, etc. using aspects of the disclosure. Correspondingly, any description herein of particular features, capabilities, or intended purposes of a device or system is generally intended to include disclosure of a method of using such devices for the intended purposes, of a method of otherwise implementing such capabilities, of a method of manufacturing relevant components of such a device or system (or the device or system as a whole), and of a method of installing disclosed (or otherwise known) components to support such purposes or capabilities. Similarly, unless otherwise indicated or limited, discussion herein of any method of manufacturing or using for a particular device or system, including installing the device or system, is intended to inherently include disclosure, as aspects of the disclosure, of the utilized features and implemented capabilities of such device or system.

In some examples, aspects of the disclosure, including computerized implementations of methods according to the disclosure, can be implemented as a system, method, apparatus, or article of manufacture using standard programming or engineering techniques to produce software, firmware, hardware, or any combination thereof to control a processor device (e.g., a serial or parallel general purpose or specialized processor chip, a single- or multi-core chip, a microprocessor, a field programmable gate array, any variety of combinations of a control unit, arithmetic logic unit, and processor register, and so on), a computer (e.g., a processor device operatively coupled to a memory), or another electronically operated controller to implement aspects detailed herein. Accordingly, for example, aspects of the disclosure can be implemented as a set of instructions, tangibly embodied on a non-transitory computer-readable media, such that a processor device can implement the instructions based upon reading the instructions from the computer-readable media.

Some aspects of the disclosure can include (or utilize) a control device such as an automation device, a special purpose or general-purpose computer including various computer hardware, software, firmware, and so on, consistent with the discussion above. As specific examples, a control device can include a processor, a microcontroller, a field-programmable gate array, a programmable logic controller, logic gates etc., and/or other typical components that are known in the art for implementation of appropriate functionality (e.g., memory, communication systems, power sources, user interfaces and other inputs, etc.). In some examples, a control device can include a centralized hub controller that receives, processes and (re) transmits control signals and other data to and from other distributed control devices (e.g., an engine controller, an implement controller, a drive controller, etc.), including as part of a hub-and-spoke architecture or otherwise.

The term “article of manufacture” as used can encompass a computer program accessible from any computer-readable device, carrier (e.g., non-transitory signals), or media (e.g., non-transitory media). For example, computer-readable media can include but are not limited to magnetic storage devices (e.g., hard disk, floppy disk, magnetic strips, and so on), optical disks (e.g., compact disk (CD), digital versatile disk (DVD), and so on), smart cards, and flash memory devices (e.g., card, stick, and so on). Additionally, it should be appreciated that a carrier wave can be employed to carry computer-readable electronic data such as those used in transmitting and receiving electronic mail or in accessing a network such as the Internet or a local area network (LAN). Those skilled in the art will recognize that many modifications may be made to these configurations without departing from the scope or spirit of the disclosure.

Certain operations of methods according to the disclosure, or of systems executing those methods, may be represented schematically in the drawings, or otherwise discussed herein. Unless otherwise specified or limited, representation in the drawings of particular operations in particular spatial order may not necessarily require those operations to be executed in a particular sequence corresponding to the particular spatial order. Correspondingly, certain operations represented in the drawings, or otherwise disclosed herein, can be executed in different orders than are expressly illustrated or described, as appropriate for a given implementation. Further, in some examples, certain operations can be executed in parallel, including by dedicated parallel processing devices, or separate computing devices configured to interoperate as part of a large system.

As used herein in the context of computer implementations, unless otherwise specified or limited, the terms “component”, “system”, “module”, “block”, and the like are intended to encompass part or all of computer-related systems that include hardware, software, a combination of hardware and software, or software in execution. For example, a component may be, but is not limited to being, a processor device, a process being executed (or executable) by a processor device, an object, an executable, a thread of execution, a computer program, or a computer. By way of illustration, both an application running on a computer and the computer can be a component. One or more components (or system, module, and so on) may reside within a process or thread of execution, may be localized on one computer, may be distributed between two or more computers or other processor devices, or may be included within another component (or system, module, and so on).

Also, as used herein, unless otherwise limited or defined, terms such as “about”, “substantially”, and “approximately” refer to a range of values ±5% of the numeric value that the term precedes. As a default, the terms “about” and “approximately” are inclusive to the endpoints of the relevant range, but disclosure of ranges exclusive to the endpoints is also intended.

Also, as used herein, unless otherwise limited or defined, terms such as “integral” and derivatives thereof (e.g., “integrally”) describe elements that are manufacture as a single piece without fasteners, adhesive, or the like to secure separate components together. For example, an element stamped as a single-piece component from a single piece of sheet metal, without rivets, screws, or adhesive to hold separately formed pieces together is an integral (and integrally formed) element. In contrast, an element formed from multiple pieces that are separately formed initially then later connected together, is not an integral (or integrally formed) element.

Also, as used herein, unless otherwise defined or limited, the term “lateral” refers to a direction that does not extend in parallel with a reference direction. A feature that extends in a lateral direction relative to a reference direction thus extends in a direction, at least a component of which is not parallel to the reference direction. In some cases, a lateral direction can be a radial or other perpendicular direction relative to a reference direction.

1. A cooling system, comprising:
a power source;
a first pump cassette to circulate fluid through the cooling system, the first pump cassette connected to the power source and comprising a first inrush current limiter circuit and a first pump controller; and
a second pump cassette to circulate fluid through the cooling system in parallel with the first pump cassette, the second pump cassette connected to the power source and comprising a second inrush current limiter circuit and a second pump controller;
wherein the first inrush current limiter circuit is connected in series between the power source and the first pump controller, the first inrush current limiter circuit being configured to electrically isolate the first pump controller from the power source by limiting current flow from the power source to the first pump controller; and
wherein the second inrush current limiter circuit is connected in series between the power source and the second pump controller, the second inrush current limiter circuit being configured to electrically isolate the second pump controller from the power source by limiting current flow from the power source to the second pump controller.

2. The cooling system of claim 1, wherein the first pump cassette is hot-swappable such that the first pump cassette is removable from the cooling system without causing the cooling system to shut down.

3. The cooling system of claim 2, wherein the second pump cassette is hot-swappable such that the second pump cassette is removable from the cooling system without causing the cooling system to shut down.

4. The cooling system of claim 1, wherein the first inrush current limiter circuit consists essentially of a first printed circuit board (PCB) assembly and the second inrush current limiter circuit consists essentially of a second PCB assembly.

5. The cooling system of claim 1, wherein the first inrush current limiter circuit comprises a first N-channel metal-oxide-semiconductor field-effect transistor (MOSFET) and the second inrush current limiter circuit comprises a second N-channel MOSFET.

6. The cooling system of claim 1, wherein the first inrush current limiter circuit is connected to the power source via a first two-pin electrical connector and the second inrush current limiter circuit is connected to the power source via a second two-pin electrical connector.

7. The cooling system of claim 1, wherein the first pump controller comprises a first variable frequency drive and the second pump controller comprises a second variable frequency drive.

8. A cooling system, comprising:
a power source;
a first pump cassette to circulate fluid through the cooling system, the first pump cassette connected to the power source and comprising a first inrush current limiter circuit and a first pump controller; and
a second pump cassette to circulate fluid through the cooling system, the second pump cassette connected to the power source and comprising a second inrush current limiter circuit and a second pump controller;
wherein the first inrush current limiter circuit is connected in series between the power source and the first pump controller, the first inrush current limiter circuit being configured to electrically isolate the first pump controller from the power source by limiting current flow from the power source to the first pump controller; and
wherein the second inrush current limiter circuit is connected in series between the power source and the second pump controller, the second inrush current limiter circuit being configured to electrically isolate the second pump controller from the power source by limiting current flow from the power source to the second pump controller.

9. The cooling system of claim 8, wherein the first pump cassette is hot-swappable such that the first pump cassette is removable from the cooling system without causing the cooling system to shut down, and wherein the second pump cassette is hot-swappable such that the second pump cassette is removable from the cooling system without causing the cooling system to shut down.

10. The cooling system of claim 8, wherein the first pump cassette and the second pump cassette operate in parallel to circulate fluid through the cooling system.

11. The cooling system of claim 8, wherein the first inrush current limiter circuit comprises:
a switched-mode power supply circuit configured to convert electrical power from the power source into an output voltage using a switching regulator; and
a switching circuit configured to receive the output voltage and limit current flow to the first pump controller using a transistor.

12. The cooling system of claim 11, wherein the second inrush current limiter circuit comprises:
a second switched-mode power supply circuit configured to convert electrical power from the power source into a second output voltage using a second switching regulator; and
a second switching circuit configured to receive the second output voltage and limit current flow to the second pump controller using a second transistor.

13. The cooling system of claim 12, wherein the transistor comprises an N-channel MOSFET and the second transistor comprises a second N-channel MOSFET.

14. A cooling system, comprising:
a power source;
a first pump cassette to circulate fluid through the cooling system, the first pump cassette connected to the power source and comprising a first inrush current limiter circuit and a first pump controller, the first pump cassette being hot-swappable such that the first pump cassette is removable from the cooling system without causing the cooling system to shut down; and
a second pump cassette to circulate fluid through the cooling system, the second pump cassette connected to the power source and comprising a second inrush current limiter circuit and a second pump controller, the second pump cassette being hot-swappable such that the second pump cassette is removable from the cooling system without causing the cooling system to shut down;
wherein the first inrush current limiter circuit is connected in series between the power source and the first pump controller, the first inrush current limiter circuit being configured to electrically isolate the first pump controller from the power source by limiting current flow from the power source to the first pump controller; and
wherein the second inrush current limiter circuit is connected in series between the power source and the second pump controller, the second inrush current limiter circuit being configured to electrically isolate the second pump controller from the power source by limiting current flow from the power source to the second pump controller.

15. The cooling system of claim 14, wherein the first pump cassette and the second pump cassette operate in parallel to circulate fluid through the cooling system.

16. The cooling system of claim 14, wherein the first pump controller comprises a first variable frequency drive and the second pump controller comprises a second variable frequency drive.

17. The cooling system of claim 14, wherein the first inrush current limiter circuit consists essentially of a first PCB assembly and the second inrush current limiter circuit consists essentially of a second PCB assembly.

18. The cooling system of claim 14, wherein the first inrush current limiter circuit comprises:
a switched-mode power supply circuit configured to convert electrical power from the power source into an output voltage using a switching regulator; and
a switching circuit configured to receive the output voltage and limit current flow to the first pump controller using a positive leg of a transistor.

19. The cooling system of claim 18, wherein the second inrush current limiter circuit comprises:
a second switched-mode power supply circuit configured to convert electrical power from the power source into a second output voltage using a second switching regulator; and
a second switching circuit configured to receive the second output voltage and limit current flow to the second pump controller using a positive leg of a second transistor.

20. The cooling system of claim 19, wherein the transistor comprises an N-channel MOSFET and the second transistor comprises a second N-channel MOSFET.
